(19) United States
(12) Patent Application Publication
(10) Pub. No.: US 2024/0282706 A1
(43) Pub. Date: Aug. 22, 2024

(54) SEMICONDUCTOR DEVICE

(71) Applicant: Samsung Electronics Co., Ltd., Suwon-si (KR)

(72) Inventor: Myeonghoon HONG, Suwon-si (KR)

(73) Assignee: Samsung Electronics Co., Ltd., Suwon-si (KR)

(21) Appl. No.: 18/502,563

(22) Filed: Nov. 6, 2023

(30) Foreign Application Priority Data
Feb. 16, 2023 (KR) 10-2023-0020602

(51) Int. Cl. H01L 23/528; G11C 16/04; H01L 23/522; H10B 41/10; H10B 41/27; H10B 41/35; H10B 41/40; H10B 43/10; H10B 43/27; H10B 43/35; H10B 43/40

(52) U.S. Cl. CPC H01L 23/5283; G11C 16/0483; H01L 23/5226; H10B 41/10; H10B 41/27; H10B 41/35; H10B 41/40; H10B 43/10; H10B 43/27; H10B 43/35; H10B 43/40

(57) ABSTRACT

A semiconductor device may include a lower substrate; an active region on the lower substrate; a common source plate spaced apart from an upper surface of the lower substrate in a vertical direction, and the common source plate overlapping the upper surface of the lower substrate; a discharge structure directly connecting the common source plate and the active region in the vertical direction, and the discharge structure having a wall shape extending in a first direction parallel to the upper surface of the lower substrate; and a cell array structure on the common source plate. A length of the discharge structure in the first direction may be greater than a width of the discharge structure in a second direction parallel to the upper surface of the lower substrate and perpendicular to the first direction.

### CROSS-REFERENCE TO RELATED APPLICATION

This application claims priority under 35 USC § 119 to Korean Patent Application No. 10-2023-0020602, filed on Feb. 16, 2023, in the Korean Intellectual Property Office (KIPO), the contents of which are incorporated by reference herein in their entirety.

### BACKGROUND

Various example embodiments relate to semiconductor devices. For example, various example embodiments relate to a vertical memory device.

As information communication devices become multifunctional, memory cells included in a semiconductor device may have a large capacity and may be highly integrated. Alternatively or additionally, a size of each of the memory cells may gradually decrease, and operating circuits and/or wiring structures included in the semiconductor device for operation and/or electrical connection of the semiconductor device may be more complicated. Accordingly, processes for manufacturing the semiconductor device may be complicated, and/or electrical defects may occur during the processes for manufacturing the semiconductor device.

### SUMMARY

Various example embodiments provide a semiconductor device having improved or excellent electrical characteristics and/or high reliability.

According to some example embodiments, there is provided a semiconductor device comprising a lower substrate, an active region on the lower substrate, a common source plate spaced apart from an upper surface of the lower substrate in a vertical direction, and the common source plate at least partly overlapping the upper surface of the lower substrate, a discharge structure directly connecting the common source plate and the active region in the vertical direction, the discharge structure having a structure in which a plurality of discharge contact plugs and a plurality of discharge conductive patterns are alternately stacked, and a cell array structure on the common source plate. The discharge contact plugs extend parallel to the upper surface of the lower substrate, and the conductive patterns extend parallel to the upper surface of the lower substrate.

Alternatively or additionally according to some example embodiments, there is provided a semiconductor device comprising a lower substrate, an active region on the lower substrate, a common source plate spaced apart from an upper surface of the lower substrate in a vertical direction, the common source plate at least partly overlapping the upper surface of the lower substrate, a discharge structure directly connecting the common source plate and the active region in the vertical direction, the discharge structure having a wall shape extending in a first direction parallel to the upper surface of the lower substrate, and a cell array structure on the common source plate. A length of the discharge structure in the first direction is greater than a width of the discharge structure in a second direction parallel to the upper surface of the lower substrate and perpendicular to the first direction.

Alternatively or additionally according to some example embodiments, there is provided a semiconductor device comprising a lower substrate, a peripheral circuit including a peripheral circuit pattern and a multilayer wiring structure on the lower substrate, an active region on the lower substrate, the active region including N-type impurities, a common source plate spaced apart from an upper surface of the lower substrate in a vertical direction, the common source plate at least partly overlapping the upper surface of the lower substrate, a discharge structure directly connecting the common source plate and the active region in the vertical direction, the discharge structure including a plurality of discharge contact plugs and a plurality of discharge conductive patterns alternately stacked, a gate stack on the common source plate, the gate stack including a plurality of gate patterns spaced apart from each other in the vertical direction and an insulation layer interposed between the gate patterns, and a channel structure passing through the gate stack in the vertical direction, the channel structure contacting an upper portion of the common source plate. The discharge conductive patterns and the discharge contact plugs extend in a first direction parallel to the upper surface of the lower substrate such that the first direction is a long axis direction of each of discharge conductive patterns and the discharge contact plugs, and a length of each of the discharge contact plugs in the first direction is greater than a width of each of the discharge conductive patterns contacting each discharge contact plugs.

In the vertical memory device according to various example embodiments, the discharge contact plugs and the discharge conductive patterns included in the discharge structure may have a shape extending in the long axis direction, so that a volume of the discharge structure serving as a path for discharging may be increased. As the volume of the path for discharging may be increased, discharging efficiency may be increased. Therefore, the vertical memory device may have a high reliability and/or improved or excellent electrical characteristics.

### BRIEF DESCRIPTION OF THE DRAWINGS

Various example embodiments will be more clearly understood from the following detailed description taken in conjunction with the accompanying drawings. FIGS. 1 to 34 represent various non-limiting, example embodiments as described herein.

FIG. 1 is a block diagram of a semiconductor device according to various example embodiments;

FIG. 2 is an equivalent circuit diagram of a memory cell array in the semiconductor device according to various example embodiments;

FIG. 3 is a schematic perspective view of a vertical memory device having a COP structure according to various example embodiments;

FIG. 4 is a plan view illustrating a portion of a vertical memory device according to various example embodiments;

FIG. 5 is a perspective view schematically illustrating a portion of a vertical memory device according to various example embodiments;

FIGS. 6 and 7 are cross-sectional views of a portion of a vertical memory device according to various example embodiments;

FIGS. 8 and 9 are a plan view and a perspective view, respectively, illustrating a portion of a vertical memory device according to various example embodiments;

FIGS. 10 and 11 are a plan view and a perspective view, respectively, illustrating a portion of a vertical memory device according to some example embodiments;

FIGS. 12 and 13 are a plan view and a perspective view, respectively, illustrating portion of a vertical memory device according to various example embodiments;

FIG. 14 is a perspective view illustrating a portion of a semiconductor device according to various example embodiments;

FIGS. 15 and 16 are a plan view and a perspective view, respectively, illustrating portions of a vertical memory device according to various example embodiments;

FIGS. 17 and 18 are a plan view and a perspective view illustrating portions of a vertical memory device according to various example embodiments;

FIGS. 19 to 30 are cross-sectional views illustrating a method of manufacturing a vertical memory device according to various example embodiments;

FIG. 31 is a cross-sectional view of a vertical memory device according to various example embodiments;

FIGS. 32 and 33 are cross-sectional views illustrating a method of manufacturing a vertical memory device according to various example embodiments; and

FIG. 34 is a diagram schematically illustrating an electronic system including a semiconductor device according to various example embodiments.

### DETAILED DESCRIPTION

Hereinafter, various example embodiments will be described in detail with reference to the accompanying drawings.

Hereinafter, a direction parallel to a surface of a substrate may be referred to as a first direction X, and a direction parallel to the surface of the substrate and perpendicular to the first direction X may be referred to as a second direction Y. In addition, a direction perpendicular to the surface of the substrate may be referred to as a vertical direction Z.

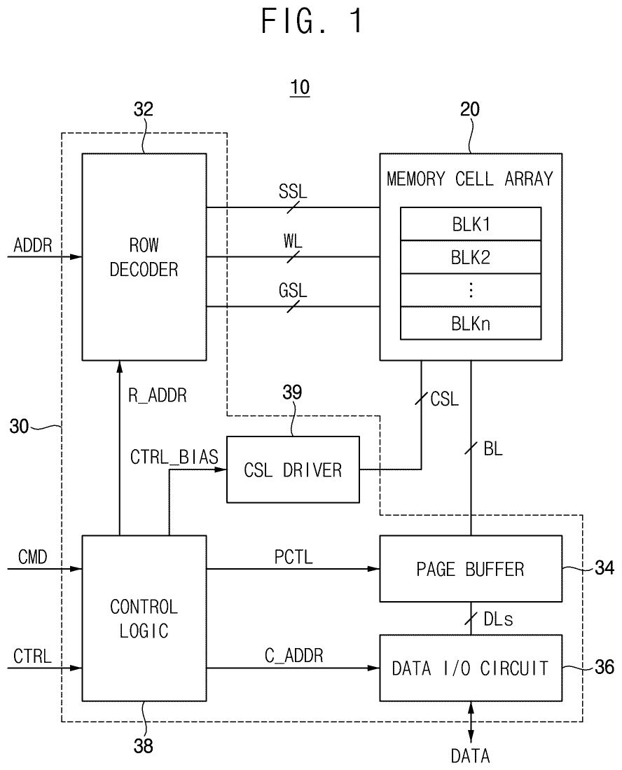

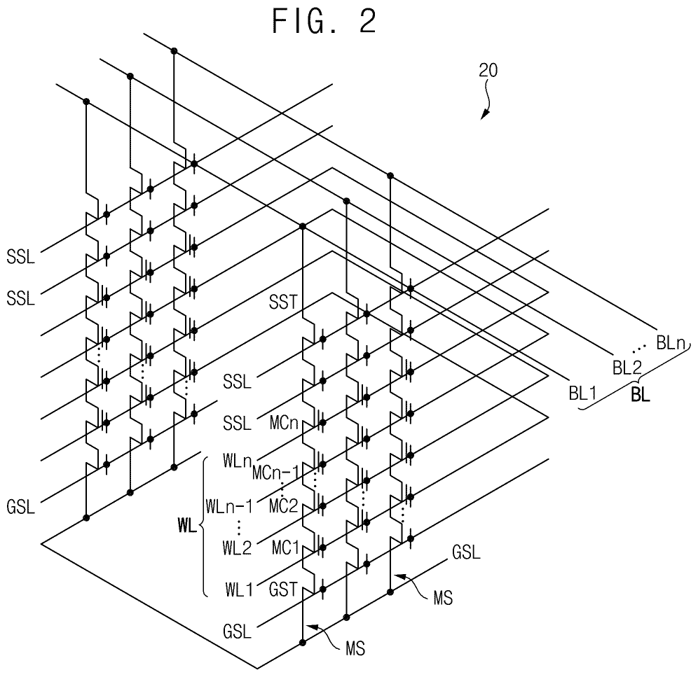

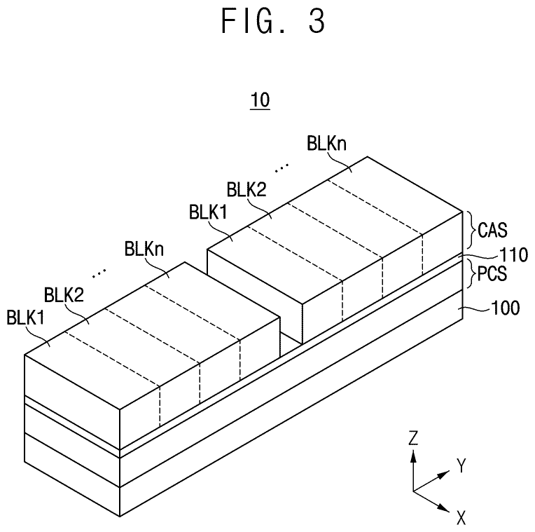

FIG. 1 is a block diagram of a semiconductor device according to various example embodiments. FIG. 2 is an equivalent circuit diagram of a memory cell array in the semiconductor device according to various example embodiments. FIG. 3 is a schematic perspective view of a vertical memory device having a cell-over-periphery (COP) structure according to various example embodiments.

Referring to FIGS. 1 to 3, a semiconductor device 10 may include a memory cell array 20 and a peripheral circuit 30. The memory cell array 20 may include a plurality of memory cell blocks BLK1, BLK2, . . . , BLKn. A plurality of memory cells may be included in each of the plurality of memory cell blocks BLK1, BLK2, . . . , BLKn, for example, the same number of memory cells may be included in each of the plurality of memory cell blocks BLK1, BLK2, . . . , BLKn. The plurality of memory cells may include at least a portion of a bit line BL, at least a portion of a word line WL, at least a portion of a string select line SSL, and at least a portion of ground select line GSL, and the memory cells may be electrically connected to the peripheral circuit 30.

The peripheral circuit 30 may include, e.g. a row decoder 32, a page buffer 34, a data input/output circuit 36, a control logic 38 and a common source line CSL driver 39, etc. Although not shown in FIG. 1, the peripheral circuit 30 may further include various circuits such as a voltage generating circuit for generating various voltages necessary for or used for an operation of the semiconductor device 10, an error correcting circuit for correcting errors of read data from the memory cell array 20, and input/output interfaces, etc.

The memory cell array 20 may be connected to a page buffer 34 through the bit line BL, and may be connected to a row decoder 32 through the word line WL, the string select line SSL and the ground select line GSL. In the memory cell array 20, the plurality of memory cells included in the plurality of memory cell blocks BLK1, BLK2, . . . , BLKn may be or may include memory cells of a NAND flash memory device (however, example embodiments are not necessarily limited thereto). The memory cell array 20 may be a three-dimensional memory cell array. The three-dimensional memory cell array may include a plurality of memory cell strings, and each of the plurality of memory cell strings may include or be connected to the plurality of memory cells connected to the plurality of word lines WL vertically stacked.

As shown in FIG. 2, the memory cell array 20 may include the plurality of bit lines BL1, BL2, . . . , BLn, the plurality of word lines WL1, WL2, . . . , WLn−1, WLn, at least one string select line SSL, at least one ground select line GSL and a common source line CSL. A plurality of memory cell strings MS may be disposed between the plurality of bit lines BL and a common source line CSL.

In various example embodiments, the number of memory cell blocks may be different from the number of bit lines and/or the number of word lines. In various example embodiments, the number of word lines in each of the memory cell blocks may be the same as or different from the number of bit lines. In various example embodiments, the number of string select lines in each memory cell block may be the same as or different from the number of bit lines in the memory cell block.

FIG. 2 illustrates a case in which two string selection lines SSL are included in each memory cell string MS. However, a structure of the memory cell structure MS may not be limited thereto. For example, each of memory cell strings MS may include one string select line SSL.

Each of memory cell strings MS may include or be connected to a string select transistor SST, a ground select transistor GST and the plurality of memory cell transistors MC1, MC2, . . . , MCn−1, MCn. A drain region of the string select transistor SST may be connected to the bit line BL, and a source region of the ground select transistor GST may be connected to the common source line CSL. The common source line CSL may be or may correspond to a region where the source regions of the plurality of ground select transistors GST are commonly connected.

The string select transistor SST may be connected to the string select line SSL, and the ground select transistor GST may be connected to the ground select line GSL. The plurality of memory cell transistors MC1, MC2, . . . , MCn−1, and MCn may be connected to the plurality of word lines WL, respectively.

The peripheral circuit 30 may receive one or more of an address signal ADDR, a command signal CMD, and a control signal CTRL from an outside of the semiconductor device 10. The peripheral circuit 30 may transmit and/or receive data from an external device.

The row decoder 32 may select at least one of the plurality of memory cell blocks BLK1, BLK2, . . . , BLKn in response to an external address signal ADDR, and then may select the word line WL, the string selection line SSL and the ground selection line GSL in the selected memory cell block. The row decoder 32 may transmit a voltage for an operation, such as a program operation, an erase operation, or a read operation, of the selected word line WL in the memory cell block.

The page buffer 34 may be connected to the memory cell array 20 through the bit line BL. The page buffer 34 may operate as a write driver during a programming operation, and may apply a voltage according to write data to the bit line BL in the memory cell array 20. The page buffer 34 may operate as a sense amplifier during a read operation, and may sense the data stored in the memory cell array 20. The page buffer 34 may operate according to the control signal PCTL provided from a control logic 38.

The data input/output circuit 36 may be connected to the page buffer 34 through data lines DLs. The data input/output circuit 36 may receive data from a memory controller (not shown) during the programming operation, and the data input/output circuit 36 may transfer a program data based on a column address C_ADDR provided from the control logic 38 to the page buffer 34. The data input/output circuit 36 may transfer a read data stored in the page buffer based on a column address C_ADDR provided from the control logic 38 to the memory controller, during a read operation.

The data input/output circuit 36 may transfer the address signal or the command signal to the control logic 38 or the row decoder 32. The peripheral circuit 30 may further include an Electro Static Discharge (ESD) circuit and/or a pull-up/pull-down driver (not illustrated).

The control logic 38 may receive the command signal CMD and the control signal CTRL from the memory controller. The control logic 38 may provide a row address R_ADDR to the row decoder 32 and a column address C_ADDR to the data input/output circuit 36. The control logic 38 may generate various internal control signals used in the semiconductor device 10 in response to the control signal CTRL. For example, the control logic 38 may adjust voltage levels provided to the word line WL and the bit line BL when a memory operation, such as a program operation and/or an erase operation, is performed.

The common source line driver 39 may be connected to the memory cell array 20 through the common source line CSL. The common source line driver 39 may apply a common source voltage (e.g., a power supply voltage) and/or a ground voltage based on the control of the control logic 38 to the common source line CSL. In various example embodiments, the common source line driver 39 may be disposed under the memory cell array 20. The common source line driver 39 may vertically overlap at least a portion of the memory cell array 20.

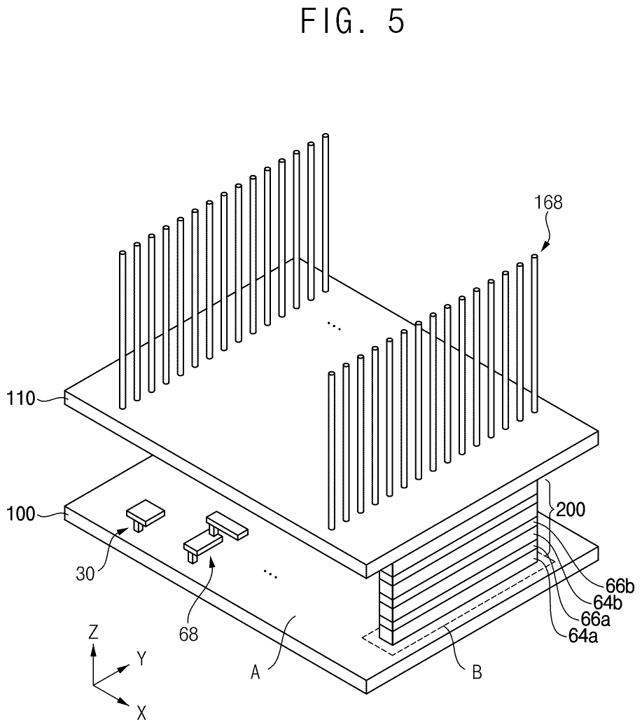

The semiconductor device may further include a discharge structure (refer to FIG. 5 200) for preventing or reducing the likelihood of and/or impact from arcing due to accumulation of electrical charges by plasma processes in manufacturing the semiconductor device. The semiconductor device may have a COP structure as shown in FIG. 3, for high integration; however, example embodiments are not limited thereto.

As shown in FIG. 3, the semiconductor device 10 may include a lower substrate 100, a peripheral circuit structure PCS, a common source plate 110 and a cell array structure CAS.

The peripheral circuit structure PCS may be on and/or at least partly in the lower substrate 100. The peripheral circuit structure PCS may include the peripheral circuit 30 and the discharge structure (refer to FIG. 5, 200). The common source plate 110 may be on the peripheral circuit structure PCS, and the cell array structure CAS may be on the common source plate 110.

The cell array structure CAS may include the plurality of memory cell blocks BLK1, BLK2, . . . , BLKn. Each of the plurality of memory cell blocks BLK1, BLK2, . . . , BLKn may include three-dimensionally arranged memory cells. The plurality of cell blocks may constitute one mat (MAT).

The discharge structure 200 may be disposed between the lower substrate 100 and the common source plate 110, and may electrically connect the lower substrate 100 and the common source plate 110 to each other.

The discharge structure 200 may include a metal, and may serve a or be configured for path for moving of charges from the common source plate 110 to the lower substrate 100. Accordingly, charges, such as triboelectric charges and/or charges generated by a plasma process such as a plasma process used in the fabrication of the memory device such as but not limited to chemical vapor deposition (CVD) processes and/or dry etching processes, may be discharged from the common source plate 110 to the lower substrate 100 through the discharge structure 200. Therefore, the charges may not be accumulated in the common source plate 110 or may be less likely to be accumulated in the common source plate.

A portion of the lower substrate 100 contacting the discharge structure 200 may serve as an impurity region, so that the impurity region may function as and/or operate as a Zener diode.

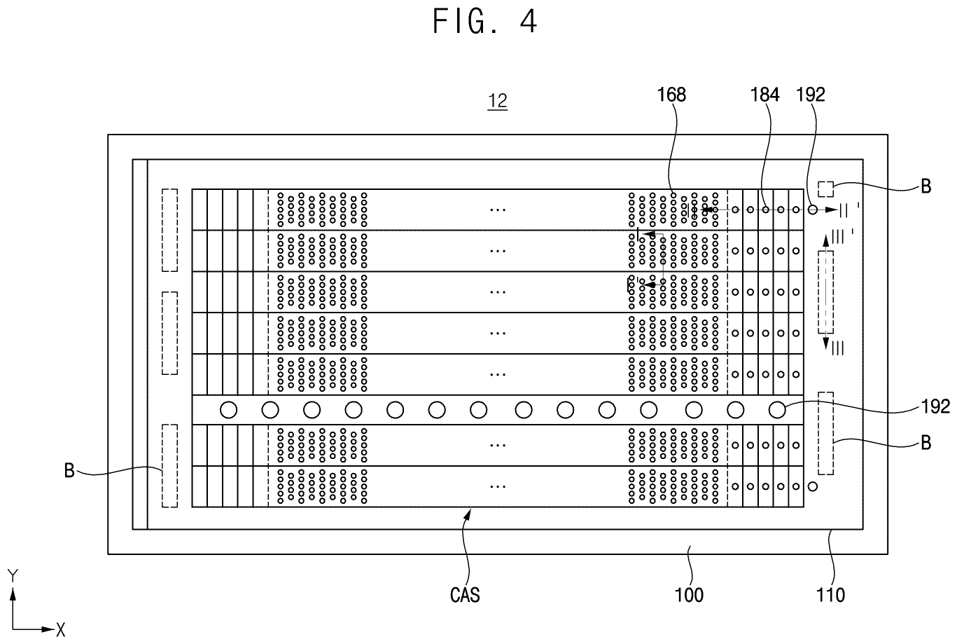

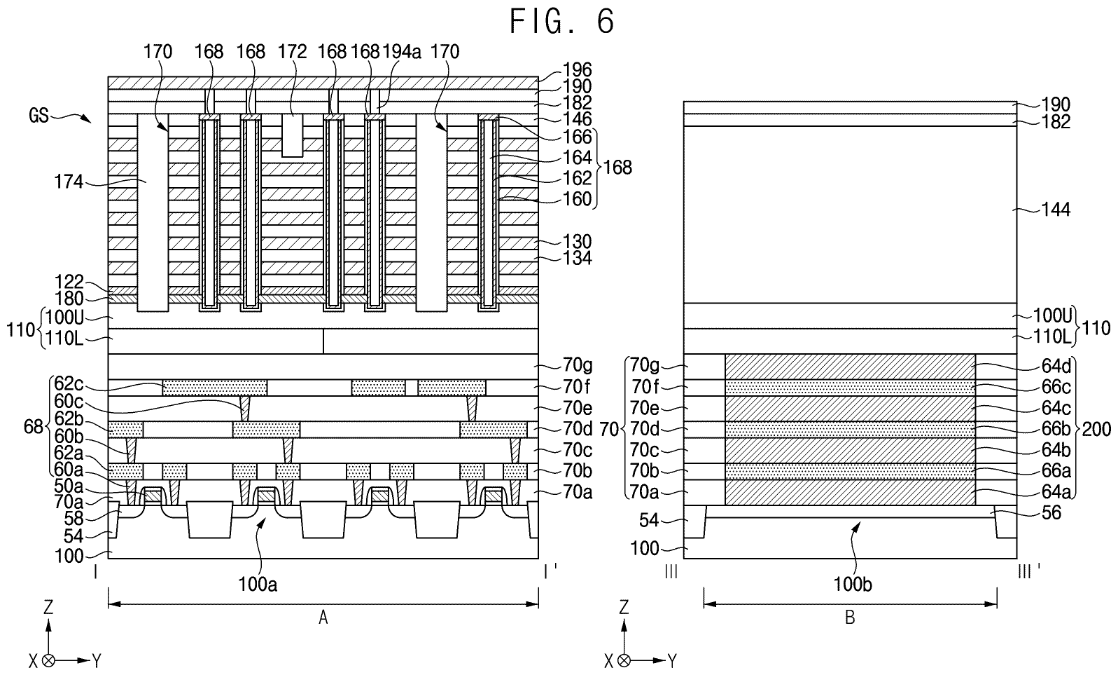

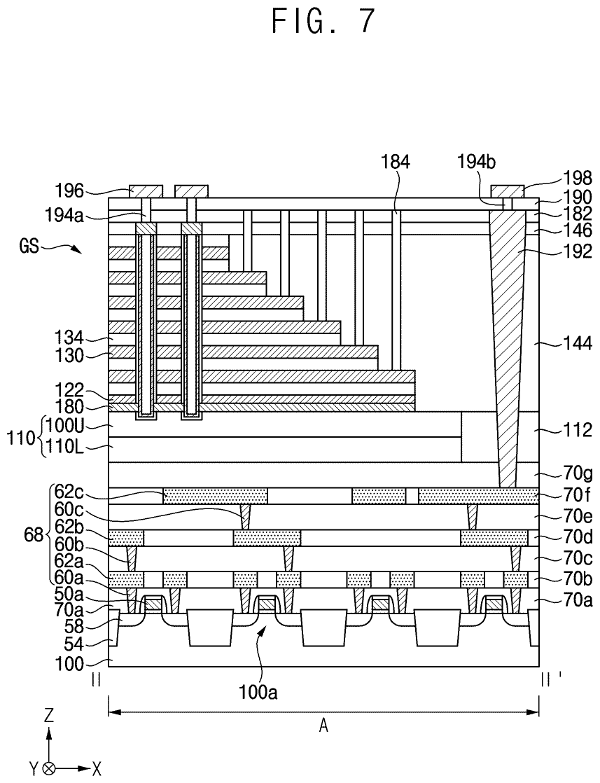

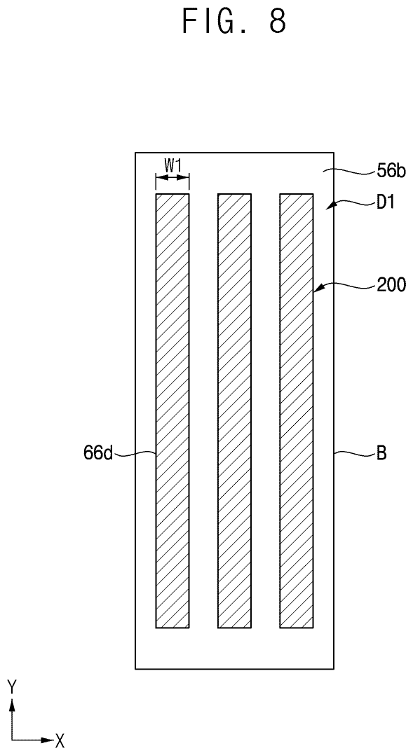

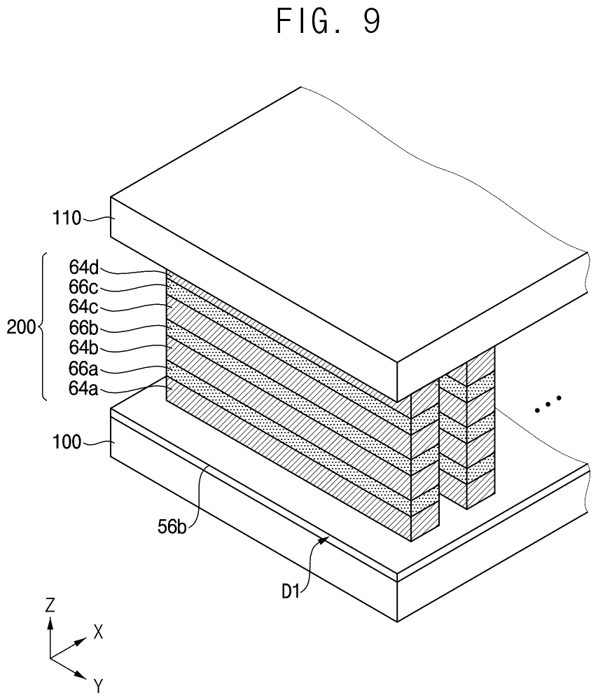

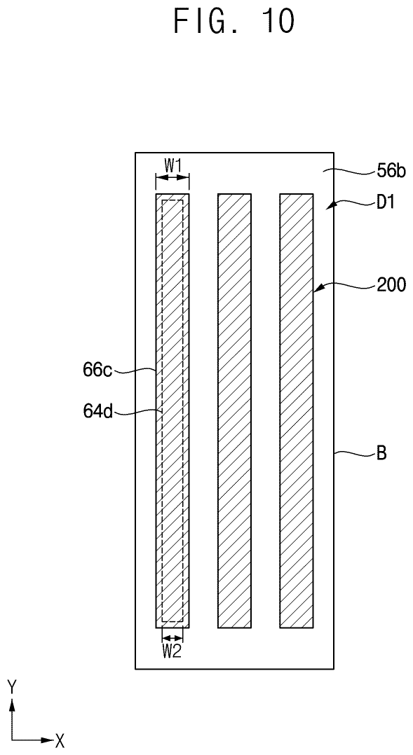

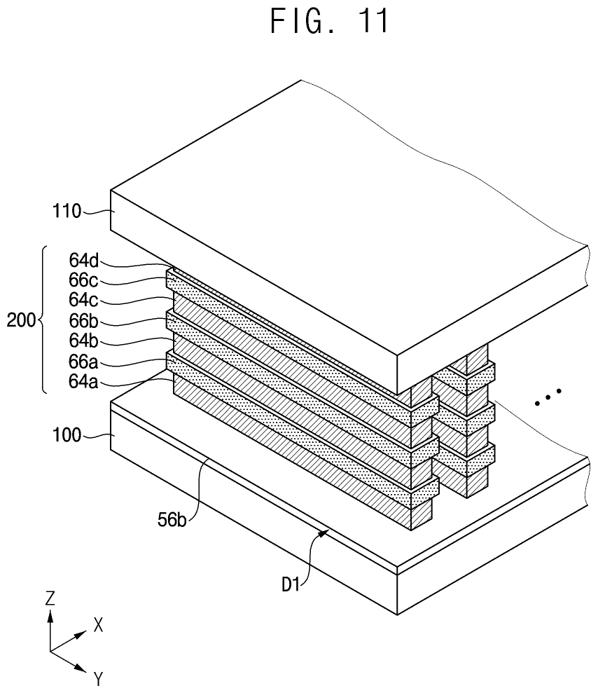

FIG. 4 is a plan view illustrating a portion of a vertical memory device according to various example embodiments. FIG. 5 is a perspective view schematically illustrating a portion of a vertical memory device according to various example embodiments. FIGS. 6 and 7 are cross-sectional views of a portion of a vertical memory device according to various example embodiments. FIGS. 8 and 9 are a plan view and a perspective view, respectively, illustrating a portion of a vertical memory device according to various example embodiments. FIGS. 10 and 11 are a plan view and a perspective view, respectively, illustrating a portion of a vertical memory device according to some example embodiments.

FIG. 4 is a plan view illustrating a MAT region in the vertical memory device. FIG. 6 is a cross-sectional view taken along line I-I′ and line III-III′ of FIG. 4. FIG. 7 is a cross-sectional view taken along line II-II of FIG. 4. FIGS. 8 and 9 illustrate discharge structures. FIGS. 10 and 11 illustrate discharge structures. FIG. 5 illustrates channel structures on a common source plate.

Referring to FIGS. 4 to 9, a semiconductor device 10 may include a peripheral circuit structure on a lower substrate 100, a common source plate 110 on the peripheral circuit structure, and a cell array structure CAS on the common source plate 110.

The common source plate 110 may be spaced apart from an upper surface of the lower substrate 100 in the vertical direction, and may overlap or at least partly overlap the upper surface of the lower substrate 100. A plurality of MAT regions 12 may be disposed on the common source plate 110 constituting or included in one semiconductor chip. In FIG. 4, only one MAT region may be shown for simplicity. However, in various example embodiments, the plurality of MAT regions 12 may be arranged in the one memory chip.

The lower substrate 100 may be or may include a semiconductor substrate. For example, the lower substrate 100 may include one or more of Si, Ge, or SiGe, and may or may not be doped with impurities such as but not limited to boron.

The peripheral circuit structure may include a peripheral circuit and the discharge structure 200. The lower substrate 100 may include a first region A for forming the peripheral circuit and a second region B for forming the discharge structure 200.

An isolation pattern 54 may be formed on the lower substrate 100, and a region where the isolation pattern 54 is not formed may be defined as an active region. A first active region 100a may be positioned on the first region A of the lower substrate 100, and a second active region 100b may be positioned on the second region B of the lower substrate 100.

A peripheral circuit pattern and a multilayer wiring structure 68 electrically connected to the peripheral circuit pattern may be disposed on the first region A of the lower substrate 100. The discharge structure 200 may be disposed on the second region B of the lower substrate 100.

The peripheral circuit pattern and the multilayer wiring structure 68 may configure various circuits included in the peripheral circuit 30 described with reference to FIG. 1.

In various example embodiments, the peripheral circuit pattern may include a plurality of passive devices such as but not limited to resistors and/or capacitors and/or inductors, and/or active devices such as but not limited to diodes and/or transistors, constituting or included in the peripheral circuit. Each of the plurality of transistors may include a lower gate 50a and second impurity regions 58 in the first active region 100a adjacent to both sides of the lower gate 50a. Each of the impurity regions 58 may serve as a source region or a drain region of the transistor.

Although the plurality of transistors are illustrated as being planar, example embodiments are not limited thereto, and one or more of the plurality of transistors may be three-dimensional. Additionally or alternatively, although the plurality of transistors are illustrated as extending in the X direction, example embodiments are not limited thereto, and one or more of the plurality of transistors may extend in the Y direction.

A lower insulating interlayer 70 having multi-layers may cover the lower substrate 100 including the first and second regions A and B and the plurality of transistors.

The multilayer wiring structure 68 may be disposed in the lower insulating interlayer 70 on the first region A. The lower insulating interlayer 70 may cover the multilayer wiring structure 68. In various example embodiments, the multilayer wiring structure 68 may be electrically connected to the plurality of transistors.

The multilayer wiring structure 68 may include a plurality of lower contact plugs 60a, 60b and 60c and a plurality of lower conductive patterns 62a, 62b and 62c. Although three wiring levels are illustrated in the multilayer wiring structure 68, example embodiments are not limited thereto. Hereinafter, one lower contact plug may be a lower contact plug positioned at one level, and one lower insulating interlayer may be a lower insulating interlayer at one level. In various example embodiments, one lower contact plug may pass through one lower insulating interlayer. The one lower conductive pattern may contact an upper surface of the one lower contact plug. For example, the multilayer wiring structure may include at least the lower contact plug 60a disposed at a lowermost level and the lower conductive pattern 62c disposed at an uppermost level.

Each of the lower contact plugs 60a, 60b and 60c may be selectively connected to ones of the plurality of transistors and the plurality of lower conductive patterns 62a, 62b and 62c.

The plurality of lower contact plugs 60a, 60b and 60c and the plurality of lower conductive patterns 62a, 62b and 62c may include metal. In various example embodiments, the plurality of lower contact plugs 60a, 60b and 60c and the plurality of lower conductive patterns 62a, 62b and 62c may independently include tungsten. In some example embodiments, at least one of the plurality of lower contact plugs 60a, 60b and 60c and the plurality of lower conductive patterns 62a, 62b and 62c may independently include polysilicon.

In some example embodiments, the plurality of lower contact plugs 60a, 60b and 60c and the plurality of lower conductive patterns 62a, 62b and 62c may include the same material. In some example embodiments, the plurality of lower contact plugs 60a, 60b and 60c and the plurality of lower conductive patterns 62a, 62b and 62c may include different materials to each other.

Hereinafter, the multilayer wiring structure 68 including three lower contact plugs 60a, 60b and 60c and three lower conductive patterns 62a, 62b and 62c may be described. In addition, the lower insulating interlayers 70 including first to seventh lower insulating interlayers 70a, 70b, 70c, 70d, 70e, 70f and 70g may be described. The multilayer wiring structure 68 may include a first lower contact plug 60a, a first lower conductive pattern 62a, a second lower contact plug 60b, a second lower conductive pattern 62b, a third lower contact plug 60c and a third lower conductive pattern 62c stacked. However, the number of patterns and/or the number of contact plugs included in the multilayer wiring structure 68 may not be limited thereto.

In some example embodiments, the transistors and the multilayer wiring structure 68 may be configured as the row decoder 32, the page buffer 34, the data input/output circuit 36, the control logic 38 and common source line driver 39, etc.

The discharge structure 200 may be described with reference to FIGS. 6 and 8 to 11.

Referring to FIGS. 6 and 8 to 11, an entire surface of the second region B in the lower substrate 100 may serve as or correspond to the second active region 100b. The second active region 100b may include, e.g., be doped with N-type impurities, and a bulk lower substrate below the second active region 100b may include, e.g., be doped with P-type impurities. Accordingly, the second active region 100b may form or correspond to a P-N junction, so that the second active region 100b may serve as a zener diode D1.

A bottom of the discharge structure 200 may contact (e.g., directly contact) an upper surface of the second active region 100b. An upper surface of the discharge structure 200 may contact (e.g., directly contact) a lower surface of the common source plate 110. The discharge structure 200 may be directly connected with second active region 100b and the common source plate 110 in the vertical direction Z. Accordingly, the discharge structure 200 may serve as a path for discharging electrical charges, for example generated by an arcing such as arcing from one or more of triboelectricity or plasma processing.

The discharge structure 200 may be formed in the lower insulating interlayers 70 on the second region B.

The discharge structure 200 may have a structure in which the plurality of discharge runners or discharge contact plugs 64a, 64b, 64c and 64d and the plurality of discharge conductive patterns 66a, 66b and 66c are alternately stacked. The discharge structure 200 may be formed by processes the same as processes used for forming the multilayer wiring structure 68 together. The discharge structure 200 may include a number of runners or contact plugs that is one more than the number of contact plugs included in the multilayer wiring structure 68. For example, the discharge structure 200 may include at least a discharge contact plug 64a positioned at a lowermost level and a discharge contact plug 64d positioned at an uppermost level.

The discharge conductive patterns 66a, 66b and 66c included in the discharge structure 200 may be positioned at the same level as the lower conductive patterns 62a, 62b and 62c included in the multilayer wiring structure 68, respectively. The discharge conductive patterns 66a, 66b and 66c included in the discharge structure 200 may include the same material as (e.g., may be formed at the same time as) the lower conductive patterns 62a, 62b and 62c included in multilayer wiring structure 68 positioned at the same level, respectively.

Ones of the discharge contact plugs 64a, 64b and 64c included in the discharge structure 200 may be positioned at the same level as the lower contact plugs 60a, 60b and 60c included in the multilayer wiring structure 68, respectively. An uppermost discharge contact plug 64d in the discharge structure 200 may be positioned higher than a top surface of the multilayer wiring structure 68, and may contact a lower surface of the common source plate 110.

The discharge contact plugs 64a, 64b and 64c included in the discharge structure 200 may include a material that is the same as a material of the lower contact plugs 60a, 60b and 60c included in the multilayer wiring structure 68 positioned at the same level, respectively, e.g., may be formed at the same time as respective ones of the low contact plugs 60a, 60b and 60c.

The plurality of discharge contact plugs 64a, 64b, 64c and 64d and the plurality of discharge conductive patterns 66a, 66b and 66c may include metal. In some example embodiments, the plurality of discharge contact plugs 64a, 64b, 64c and 64d and the plurality of discharge conductive patterns 66a, 66b and 66c may include tungsten. Alternatively or additionally in some example embodiments, at least one of the discharge contact plugs 64a, 64b, 64c and 64d and the discharge conductive patterns 66a, 66b and 66c may include polysilicon.

For example, as shown in FIGS. 6 and 7, the discharge structure 200 may include the first discharge contact plug 64a, the first discharge conductive pattern 66a, the second discharge contact plug 64b, the second discharge conductive pattern 66b, the third discharge contact plug 64c, the third discharge conductive pattern 66c and the fourth discharge contact plug 64d stacked. An upper surface of the fourth discharge contact plug 64d positioned at the uppermost level may coplanar with an upper surface of an uppermost lower insulating interlayer (i.e., a seventh lower insulating interlayer 70g).

In the discharge structure 200, the discharge conductive patterns 66a, 66b and 66c may extend in one direction. For example, a long axis direction and a short axis direction in each of the discharge conductive patterns 66a, 66b and 66c may be defined, and each of the discharge conductive patterns 66a, 66b and 66c may extend in the long axis direction (e.g., a length direction). In some example embodiments, the long axis direction of each of the discharge conductive patterns 66a, 66b and 66c may be the same as a long axis direction of the second active region 100b.

Hereinafter, the long axis direction may be the second direction Y, and the short axis direction (e.g., a width direction) may be first direction X. However, example embodiments are not limited thereto, in some example embodiments, the long axis direction may be the first direction X, and the short axis direction may be the second direction Y.

Each of the discharge contact plugs 64a, 64b, 64c and 64d may extend in the same direction as the discharge conductive patterns 66a, 66b and 66c connected thereto. For example, each of the discharge contact plugs 64a, 64b, 64c and 64d and each of the discharge conductive patterns 66a, 66b and 66c may have the same long axis direction and the same short axis direction. Each of the discharge contact plugs 64a, 64b, 64c and 64d and each of the discharge conductive patterns 66a, 66b and 66c may extend in the long axis direction. For example, each of the discharge conductive patterns 66a, 66b and 66c and each of the discharge conductive patterns 66a, 66b and 66c may extend in the second direction Y.

A length of each of the discharge contact plugs 64a, 64b, 64c and 64d in the long axis direction may be greater than a width of each of the discharge conductive patterns 66a, 66b and 66c contacting the discharge contact plugs 64a, 64b, 64c and 64d.

Accordingly, a length of the discharge structure 200 in the second direction Y may be greater than a width of the discharge structure 200 in the first direction X. In some example embodiments, the length of the discharge structure 200 in the second direction Y may be twice or more than the width of the discharge structure 200 in the first direction X.

The discharge structure 200 may have a wall shape extending in the long axis direction. Since the discharge structure 200 has the wall shape, the discharge structure 200 may have a structure connected in the long axis direction without a portion being spaced apart from each other. Accordingly, the discharge structure 200 may have a junction area with the second active region 100b that is greater than a junction area with a second active region 100b in a discharge structure including pillars having a contact plug shape spaced apart from each other. Alternatively or additionally, a volume of the discharge structure 200 may be increased. For example, an antenna ratio of the discharge structure 200 may be different than an antenna ratio of a discharge structure including pillars having a contact plug shape spaced apart from each other. Therefore, a volume of the path for discharge in the discharge structure 200 may increase, so that a discharge efficiency of the discharge structure 200 may be increased.

In some example embodiments, the discharge conductive patterns 66a, 66b and 66c may overlap or at least partly overlap the discharge contact plugs 64a, 64b, 64c and 64d therebelow, respectively. For example, the discharge conductive patterns 66a, 66b and 66c may completely cover the upper surfaces of the discharge contact plugs 64a, 64b and 64c therebelow, respectively.

In some example embodiments, as shown in FIGS. 8 and 9, each of the discharge conductive patterns 66a, 66b and 66c may have a first width W1 in the short axis direction (e.g., the first direction, X). Each of the discharge contact plugs 64a, 64b, 64c and 64d may have the first width W1 in the first direction X.

In some example embodiments, as shown in FIGS. 10 and 11, each of the discharge conductive patterns 66a, 66b and 66c and each of the discharge contact plugs 64a, 64b, 64c and 64d may have different widths in the first direction X, respectively. For example, each of the discharge conductive patterns 66a, 66b and 66c may have a first width W1 in the first direction X, and each of the discharge contact plugs 64a, 64b, 64c and 64d may have a second width W2 that is less than the first width in the first direction X. Accordingly, portions of the discharge conductive patterns 66a, 66b and 66c may protrude from sidewalls extending in the long axis direction of the discharge structure 200.

In some example embodiments, each of the discharge conductive patterns 66a, 66b and 66c may have a first length in the long axis direction, and each of the discharge contact plugs 64a, 64b, 64c and 64d may have a length of 80% to 100% of the first length in the long axis direction. For example, as shown in FIGS. 8 and 9, each of the discharge contact plugs 64a, 64b, 64c and 64d may have a length substantially the same as a length of each of the discharge conductive patterns 66a, 66b and 66c. Alternatively or additionally, as shown in FIGS. 10 and 11, each of the discharge contact plugs 64a, 64b, 64c and 64d may have a length less than a length of each of the discharge conductive patterns 66a, 66b and 66c.

In some example embodiments, a plurality of discharge structures 200 may be disposed on the second active region 100b. The plurality of discharge structures 200 may be spaced apart from each other in a direction perpendicular to the long axis direction.

An uppermost surface of the lower insulating interlayer 70 and an upper surface of the discharge structure 200 may be coplanar with each other, and may be substantially flat.

Since the discharge structure 200 has the wall shape extending in the long axis direction, the lower insulating interlayer 70 may not be interposed between the discharge contact plugs 64a, 64b, 64c and 64d and the discharge conductive patterns 66a, 66b and 66c included in the discharge structure 200. The plurality of discharge structures 200 may be spaced apart from each other in the first direction. The lower insulating interlayer 70 may be formed in a space between the plurality of discharge structures 200 spaced apart from each other in a horizontal direction.

The common source plate 110 may be formed the uppermost surface of the lower insulating interlayer 70 and the upper surface of the discharge structure 200. The common source plate 110 may be interposed between the peripheral circuit structure PCS and the cell array structure CAS. The common source plate 110 may function as a common source line CSL as shown in FIGS. 1 and 2. In some example embodiments, the common source plate 110 may function as a source region supplying currents to vertical memory cells included in the cell array structure CAS.

In some example embodiments, the common source plate 110 may include a metal plate 110L and a semiconductor plate 110U stacked. For example, the metal plate 110L may include tungsten (W), and the semiconductor plate 110U may include doped polysilicon, but may not be limited thereto. In some example embodiments, the common source plate 110 may include only the semiconductor plate 110U without the metal plate 110L.

Meanwhile, a position of the discharge structure 200 on the lower substrate 100 may not be limited thereto, and may be disposed anywhere on the upper surface of the lower substrate 100. However, the discharge structure 200 may be formed so as not to be electrically connected to the transistors and multilayer wiring structures 68 constituting the peripheral circuit on the lower substrate 100. Therefore, the discharge structure 200 may be independently disposed to be spaced from the peripheral circuit. Accordingly, the discharge structure 200 may be disposed on the lower substrate 100 on which transistors and multilayer wiring structures 68 constituting peripheral circuit are not formed.

In some example embodiments, the second region B for forming the discharge structure 200 may be disposed on the lower substrate 100 corresponding to an edge of each of MAT region 12 in the chip region. (refer to FIG. 4) In some example embodiments, the second region B for forming the discharge structure 200 may be disposed on the lower substrate 100 corresponding to vertex portions of MAT region 12 in the chip region. (refer to FIG. 4)

The cell array structure CAS may be formed on the common source plate 110. The cell array structure CAS may include a memory stack disposed on the common source plate 110. The memory stack may include a gate stack GS and channel structures 168.

The gate stack GS may include a plurality of gate patterns 130 extending in the horizontal direction and spaced apart in the vertical direction Z. An insulation layer 134 may be interposed between the common source plate 110 and a lowermost gate pattern 130 and between the plurality of gate patterns 130.

A plurality of word line cut regions 170 may be disposed on the common source plate 110. The plurality of word line cut regions 170 may extend in the first direction X, and may across the gate stack GS. A second filling insulation pattern 174 may fill each of the plurality of word line cut regions 170.

A plurality of gate patterns 130 constituting or included in one gate stack GS may be disposed between two adjacent word line cut regions 170 on the common source plate 110, and the plurality of gate patterns 130 may be stacked to overlap each other in the vertical direction Z.

Each of the gate stacks GS may extend in the first direction X. An edge in the first direction X of each of the gate stacks GS may have a stepped shape.

The plurality of gate patterns 130 constituting or included in the gate stack GS may include the ground selection line GSL, the plurality of word lines WL, and the string selection line SSL described with reference to FIG. 3. In the gate stack GS, uppermost gate pattern 130 may be separated in the second direction Y, and a string selection line cut region may be between the uppermost two gate patterns 130. Each of the uppermost two gate patterns 130 may serve as the string selection line SSL described with reference to FIG. 3. An upper insulation pattern 172 may fill the string selection line cut region.

A plurality of channel structures 168 may pass through the gate stack GS, and may extend to the common source plate 110 in the vertical direction. A bottom of each of the channel structures 168 may contact the common source plate 110. The plurality of channel structures 168 may be spaced apart from each other in the first and second directions X and Y. Each of the plurality of channel structures 168 may include a gate dielectric layer 160, a channel pattern 162, a filling insulation pattern 164 and a capping pattern 166. The gate dielectric layer 160 may include a tunnel dielectric layer, a charge storage layer and a blocking dielectric layer sequentially stacked on the channel pattern 162. The channel pattern 162 may have a cylindrical shape or a tapered shape. The filling insulation pattern 164 may fill an inner space of the channel pattern 162. The capping pattern 166 may include polysilicon such as but not limited to doped polysilicon.

As the number of stacked gate patterns 130 increases, a height of the channel structure 168 in the vertical direction Z may increase significantly. In addition, an arrangement density of the channel structure 168 may be high, and the number of the channel structure 168 may increase in the MAT region.

In a plasma deposition process and/or a plasma etching process used for forming the channel structures 168, electrical charges generated by the plasma may be accumulated in the common source plate 110. Therefore, an arcing due to the accumulated charges in common source plate 110 may occur.

The arcing may be or may include a dielectric breakdown generated an electric arc according to an electric potential generated between conductors separated by an insulator.

In some example embodiments, as the discharge structure 200 connected to the common source plate 110 is formed, the accumulated charges may be discharged through a path of the discharge structure 200 and the lower substrate 100. In some example embodiments, the substrate 100 may be grounded, e.g., may be chucked to a ground, for example during plasma processing, which may lead to a discharge path for accumulated charges. Therefore, the arcing may decrease. In some example embodiments, the discharge structure 200 may have the wall shape, and may extend in the long axis direction. Therefore, a volume of the path for the discharge may be increased, so that a discharging efficiency may be increased.

A first insulating interlayer 144, a second insulating interlayer 146, and a third insulating interlayer 182 may cover the memory stack.

Cell contact plugs 184 may pass through the first, second, and third insulating interlayers 144, 146 and 182, and may contact upper surfaces of edges of the gate patterns 130, respectively.

A fourth insulating interlayer 190 may be on the third insulating interlayer 182 and the cell contact plug 184. A first contact 194a may pass through the fourth insulating interlayer 190 and the third insulating interlayer 182, and may contact the capping pattern 166 of the channel structure 168. A bit line 196 may be on the fourth insulating interlayer 190 and the first contact 194a.

A through via 192 may pass through the first to third insulating interlayers 144, 146, and 182 and a lower filling insulation pattern 112, and may be electrically connected to the multilayer wiring structure 68 included in the peripheral circuit structure. A second contact 194b may pass through the fourth insulating interlayer 190, and may contact the through via 192. A wiring line 198 may be on the fourth insulating interlayer 190 and the second contact 194b.

In some example embodiments, the through via 192 may be spaced apart from the gate stack GS in the horizontal direction. In some example embodiments, the through via 192 may pass through the gate stack GS without contacting the gate pattern 130.

The through via 192 may be connected to the peripheral circuit through the multilayer wiring structure 68.

As described above, the vertical memory device may include the discharge structure 200 directly connected with the lower substrate 100 and the common source plate 110. The discharge structure 200 may have the wall shape extending in the long axis direction.

The arrangement and/or the stacking structure of the discharge structure 200 may be variously modified. Hereinafter, some example embodiments of a semiconductor device including the modified discharge structure 200 may be described.

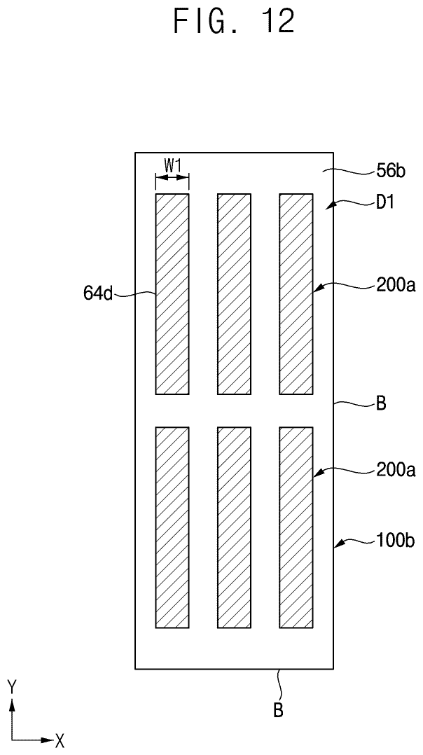

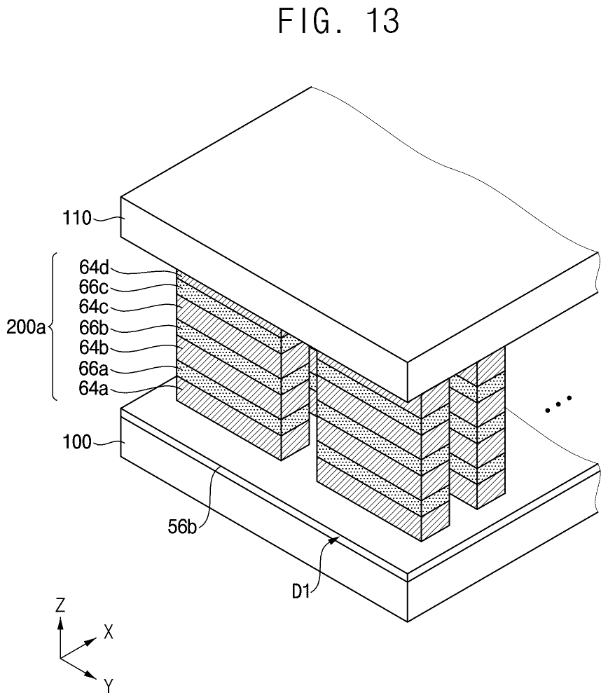

FIGS. 12 and 13 are a cross-sectional view and a perspective view, respectively, illustrating portion of a vertical memory device according to various example embodiments.

FIGS. 12 and 13 illustrate a discharge structure in the vertical memory device.

The vertical memory device may be the same as the semiconductor device described with reference to FIGS. 4 to 9, except for the discharge structure. Therefore, only the discharge structure may be described.

Referring to FIGS. 12 and 13, an entire surface of the second region B in the lower substrate 100 may serve as the second active region 100b.

A discharge structure 200a may have a structure in which a plurality of discharge contact plugs 64a, 64b, 64c and 64d and a plurality of discharge conductive patterns 66a, 66b and 66c are alternately stacked. The discharge structure 200a may be formed together by processes the same as processes for forming the multilayer wiring structure 68.

In some example embodiments, a stacked structure of the plurality of discharge contact plugs 64a, 64b, 64c and 64d and the plurality of discharge conductive patterns 66a, 66b and 66c included in the discharge structure 200a may be substantially the same as the stacked structure illustrated in FIG. 9. In some example embodiments, a stacked structure of the plurality of discharge contact plugs 64a, 64b, 64c and 64d and the plurality of discharge conductive patterns 66a, 66b and 66c included in the discharge structure may be substantially the same as the stacked structure illustrated in FIG. 11

In the discharge structure 200a, each of the discharge conductive patterns 66a, 66b and 66c may extend in one direction. For example, a long axis direction and a short axis direction in each of the discharge conductive patterns 66a, 66b and 66c may be defined, and each of the discharge conductive patterns 66a, 66b and 66c may extend in the long axis direction.

Each of the discharge contact plugs 64a, 64b, 64c and 64d may extend in a direction the same as an extension direction of the discharge conductive patterns 66a, 66b and 66c connected thereto. For example, long and short axis directions of each of the discharge contact plugs 64a, 64b, 64c and 64d may be the same as the respective long and short axis directions of each of the discharge conductive patterns 66a, 66b and 66c. The discharge contact plugs 64a, 64b, 64c and 64d and the discharge conductive patterns 66a, 66b and 66c may extend in the same long axis direction.

In some example embodiments, a plurality of discharge structures 200a may be disposed on the second active region 100b. The plurality of discharge structures 200a may be spaced apart from each other in a direction perpendicular to the long axis direction (e.g., the short axis direction). Alternatively or additionally, the plurality of discharge structures 200a may be spaced apart from each other in the long axis direction.

The discharge structure 200a may have a wall shape, and may extend in the long axis direction. Therefore, a volume of a path for the discharge may be increased, and a charge discharging efficiency may be increased.

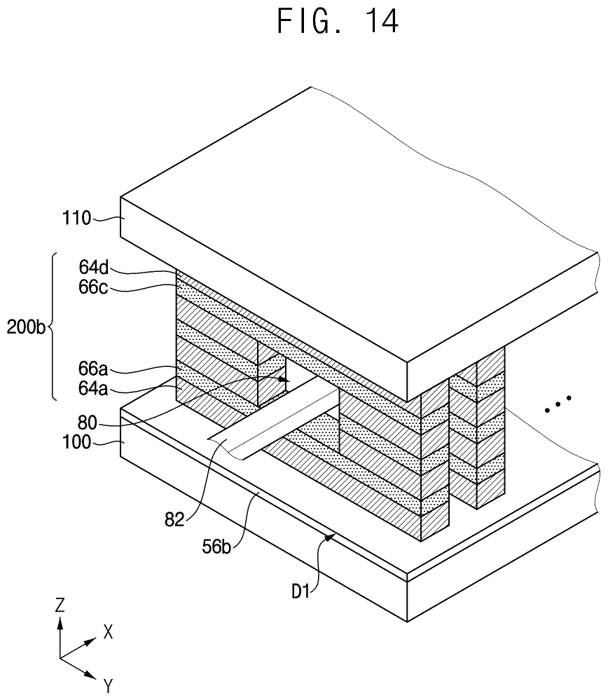

FIG. 14 is a perspective view illustrating a portion of a semiconductor device according to various example embodiments.

FIG. 14 illustrates a discharge structure of a vertical memory device.

The vertical memory device may be substantially the same as the vertical memory device described with reference to FIGS. 4 to 9, except for the discharge structure. Therefore, only the discharge structure may be described.

Referring to FIG. 14, an entire surface of the second region B in the lower substrate 100 may serve as the second active region 100b.

The discharge structure 200b may have a structure in which a plurality of discharge contact plugs 64a, 64b, 64c and 64d and a plurality of discharge conductive patterns 66a, 66b and 66c are alternately stacked. The discharge structure 200b may be formed together by processes the same as the process for forming the multilayer wiring structure 68.

In the discharge structure 200b, each of the discharge conductive patterns 66a, 66b and 66c may extend in a long axis direction. At least one discharge conductive pattern among the discharge conductive patterns 66a, 66b and 66c may include a cut portion, and may be spaced apart from each other in the long axis direction.

Each of the discharge contact plugs 64a, 64b, 64c and 64d may extend in a direction the same as an extension direction of the discharge conductive patterns 66a, 66b and 66c connected thereto. At least one of the discharge contact plugs 64a, 64b, 64c and 64d may include a cut portion in a long axis direction, and may be spaced apart from each other in the long axis direction.

In some example embodiments, at least one of the discharge conductive pattern 66a, 66b and 66c and the discharge contact plugs 64a, 64b, 64c and 64d contacting the discharge conductive pattern 66a, 66b and 66c may include the cut portion in the long axis direction. The cut portion may serve as a wire passage region 80 penetrating the discharge structure 200b in the first direction X. For example, the discharge structure 200b may have a wall shape extending in the long axis direction (e.g., the second direction), and may further include the wire passage region 80 passing through the wall of the discharge structure 200b in a short axis direction (e.g., the first direction, X).

In the discharge structure 200b, a portion where the discharge conductive patterns 66a, 66b and 66c and the discharge contact plugs 64a, 64b, 64c and 64d are spaced apart in the long axis direction may be the wire passage region 80. A lower insulating interlayer 70 may fill the wire passage region 80.

A wiring 82 may pass through the lower insulating interlayer 70 in the wire passage region 80. The wiring 82 may be electrically insulated from the discharge structure 200b. The wire 82 may extend in a direction (e.g., the first direction, X) perpendicular to the long axis direction.

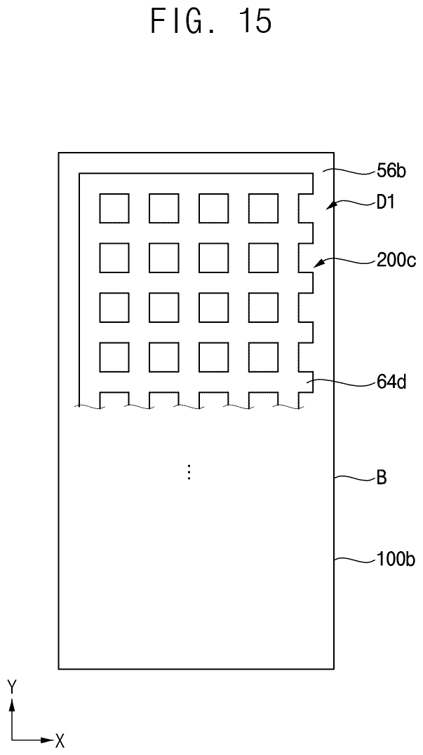

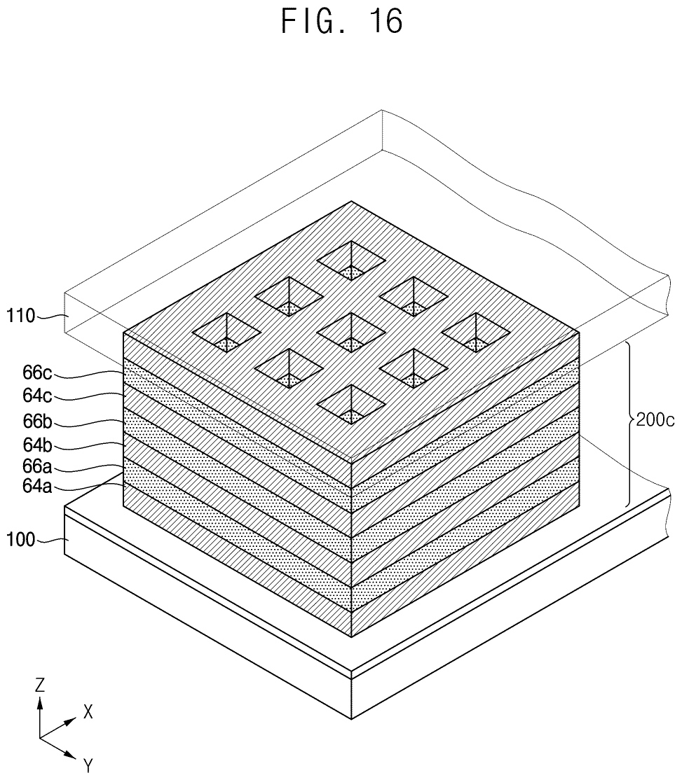

FIGS. 15 and 16 are a cross-sectional view and a perspective view, respectively, illustrating portions of a vertical memory device according to various example embodiments.

FIGS. 15 and 16 illustrate a discharge structure of the vertical memory device.

The vertical memory device may be substantially the same as the vertical memory device described with reference to FIGS. 4 to 9, except for the discharge structure. Therefore, only the discharge structure may be described.

Referring to FIGS. 15 and 16, an entire surface of the lower substrate 100 of the second region B may serve as the second active region 100b.

The discharge structure 200c may have a structure in which a plurality of discharge contact plugs 64a, 64b, 64c and 64d and a plurality of discharge conductive patterns 66a, 66b and 66c are alternately stacked. The discharge structure 200c may be formed together by processes the same as processes for forming the multilayer wiring structure 68.

In the plan view, each of the discharge conductive patterns 66a, 66b and 66c included in the discharge structure 200c may have a mesh shape including portions extending in the first direction X and portions extending in the second direction. For example, each of the discharge conductive patterns 66a, 66b and 66c may include first openings between the portions extending in the first direction X and the portions extending in the second direction Y. The first openings may be spaced apart from each other, and may be arranged in each of the first and second directions X and Y.

Each of the discharge contact plugs 64a, 64b, 64c and 64d may have a shape substantially the same as a shape of the discharge conductive patterns 66a, 66b and 66c. Each of the discharge contact plugs 64a, 64b, 64c and 64d may overlap the discharge conductive patterns 66a, 66b and 66c. In the plan view, each of the discharge contact plugs 64a, 64b, 64c and 64d included in the discharge structure 200c may have a mesh shape including portions extending in the first direction X and portions extending in the second direction Y. Each of the discharge contact plugs 64a, 64b, 64c and 64d may include second openings between the portions extending in the first direction X and portions extending in the second direction. The second openings may be spaced apart from each other, and may be arranged in each of the first and second directions X and Y. The second opening and the first opening may communicate with each other in the vertical direction.

FIG. 16 illustrates that the mesh is a square lattice of square openings; however, example embodiments are not limited thereto. For example, the mesh may be another lattice shape such as but not limited to a triangular lattice shape and/or a rectangular lattice shape. Alternatively or additionally, the openings may have a shape other than a square shape, such as but not limited to a rectangular shape that is not square.

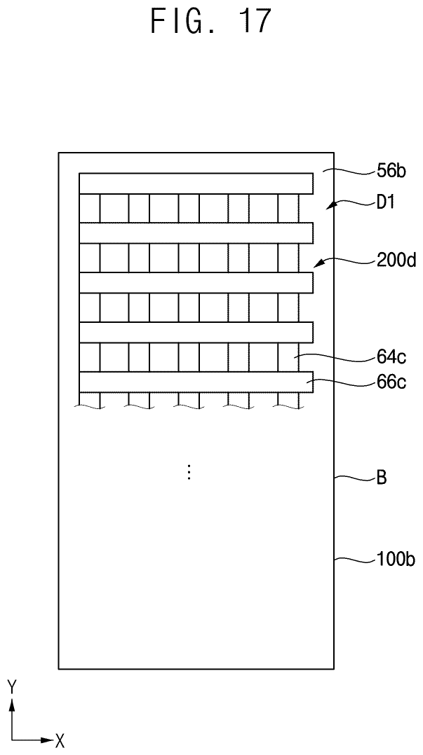

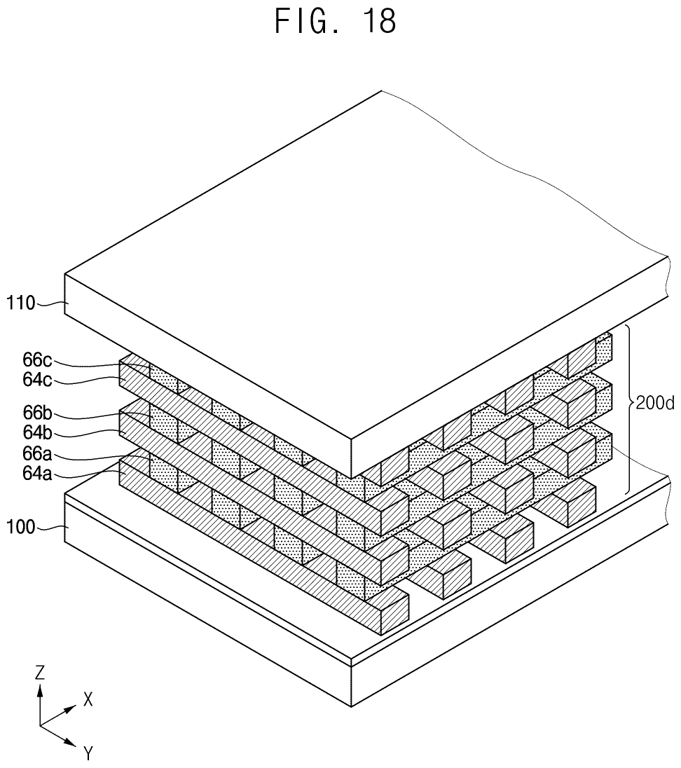

FIGS. 17 and 18 are a cross-sectional view and a perspective view illustrating portions of a vertical memory device according to various example embodiments.

FIGS. 17 and 18 illustrate a discharge structure in the vertical memory device.

The vertical memory device may be substantially the same as the vertical memory device described with reference to FIGS. 4 to 9, except for the discharge structure. Therefore, only the discharge structure may be described.

Referring to FIGS. 17 and 18, an entire surface of the second region B in the lower substrate 100 may serve as the second active region 100b.

The discharge structure 200 may have a structure in which a plurality of discharge contact plugs 64a, 64b, 64c and 64d and a plurality of discharge conductive patterns 66a, 66b and 66c are alternately stacked. The discharge structure 200c may be formed together by processes the same as processes for forming the multilayer wiring structure 68.

In the discharge structure 200c, each of the discharge conductive patterns 66a, 66b and 66c may extend in the first direction X. For example, each of the discharge conductive patterns 66a, 66b and 66c may be disposed such that the first direction X may be the long axis direction. Each of the discharge conductive patterns 66a, 66b and 66c may be spaced apart from each other in the second direction Y.

Each of the discharge contact plugs 64a, 64b, 64c and 64d may extend in the second direction Y. For example, each of the discharge contact plugs 64a, 64b, 64c and 64d may extend in a direction perpendicular to an extension direction of the discharge conductive patterns 66a, 66b and 66c connected thereto. For example, each of the discharge contact plugs 64a, 64b, 64c and 64d may be disposed such that the second direction Y may be a long axis direction. The plurality of discharge contact plugs 64a, 64b, 64c and 64d may be spaced apart from each other in the first direction X.

Accordingly, the discharge contact plugs 64a, 64b, 64c and 64d and the plurality of discharge conductive patterns 66a, 66b and 66c included in the discharge structure 200c may be alternately disposed in the vertical direction to cross each other. In the plan view, the discharge structure 200c may have a mesh shape.

Referring to FIGS. 17 and 18, a line width of the plurality of the discharge contact plugs 64a, 64b, 64c and 64d may be constant or variable, and may be the same as or different from a pitch of neighboring ones of the plurality of discharge conductive patterns 66a, 66b and 66c. Alternatively or additionally, a line width of each of the plurality of the discharge contact plugs 64a, 64b, 64c and 64d may be constant or variable and may be the same as or different from a pitch of neighboring ones of the plurality of discharge conductive patterns 66a, 66b and 66c. A line width and/or a pitch of plurality of discharge conductive patterns 66a, 66b and 66c may be the same as or different from a respective line width and/or a pitch of the plurality of discharge contact plugs 64a, 64b, 64c and 64d.

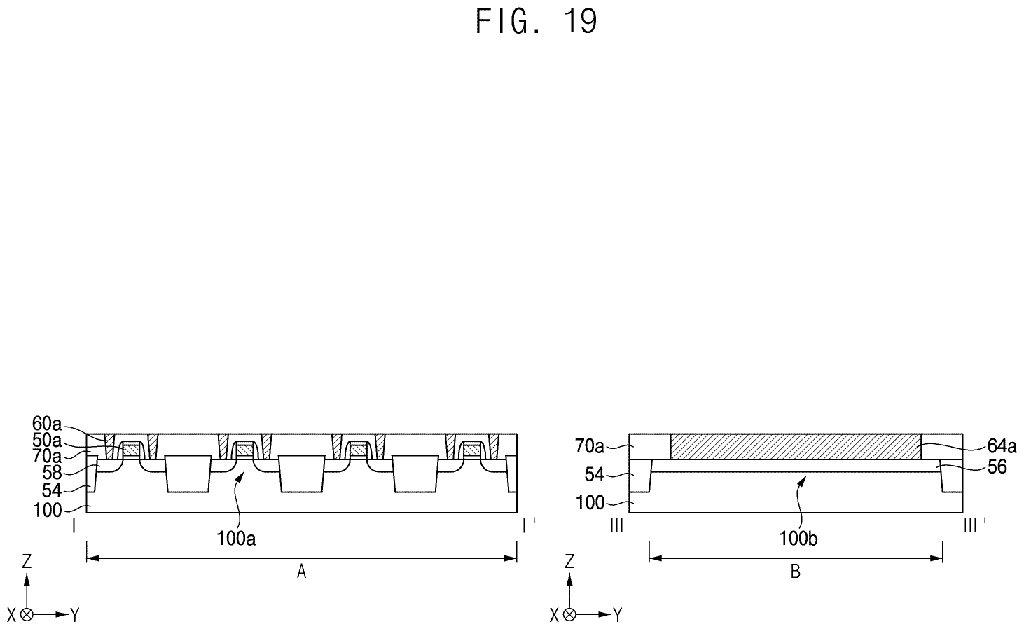

FIGS. 19 to 30 are cross-sectional views illustrating a method of manufacturing a vertical memory device according to various example embodiments.

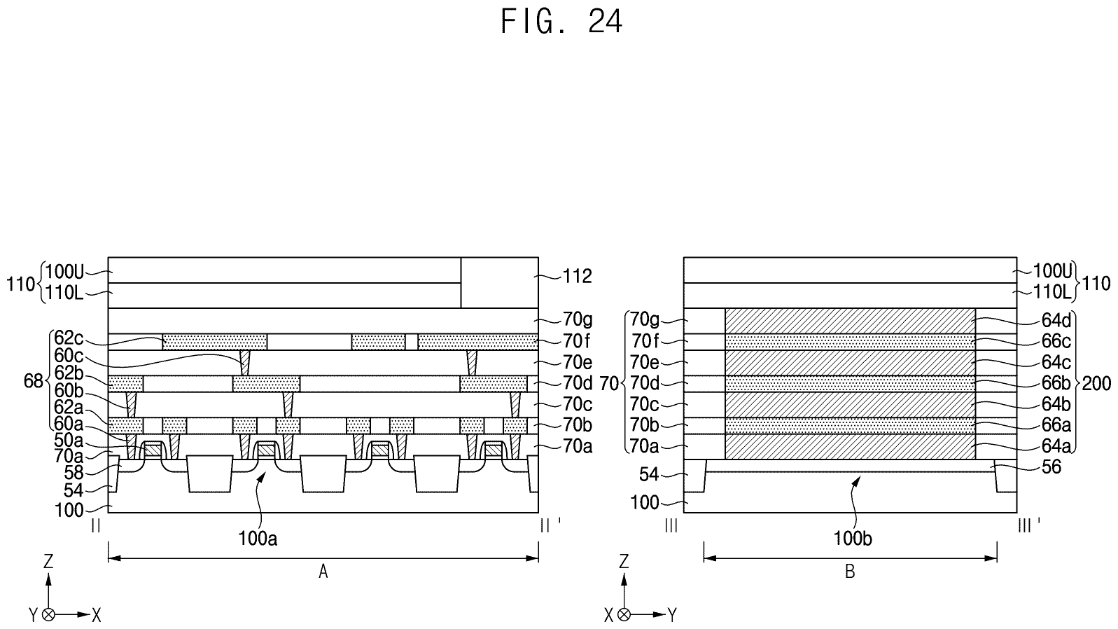

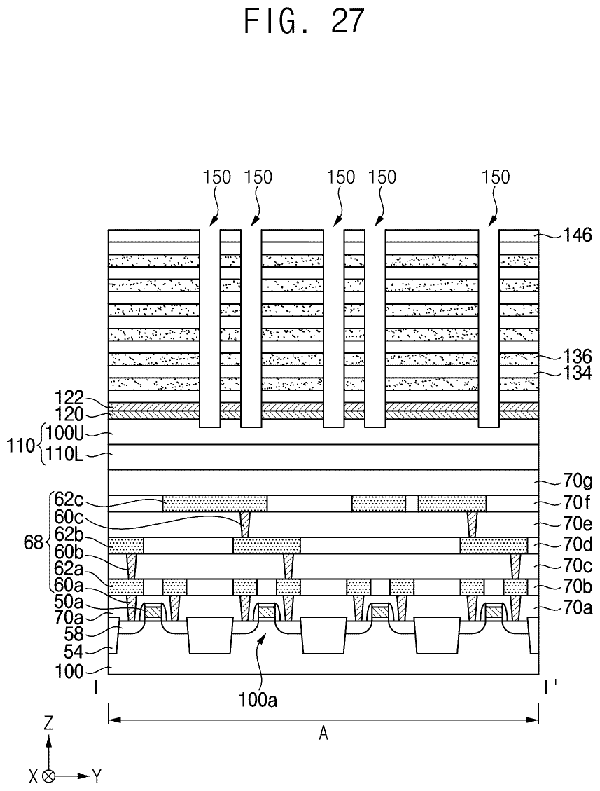

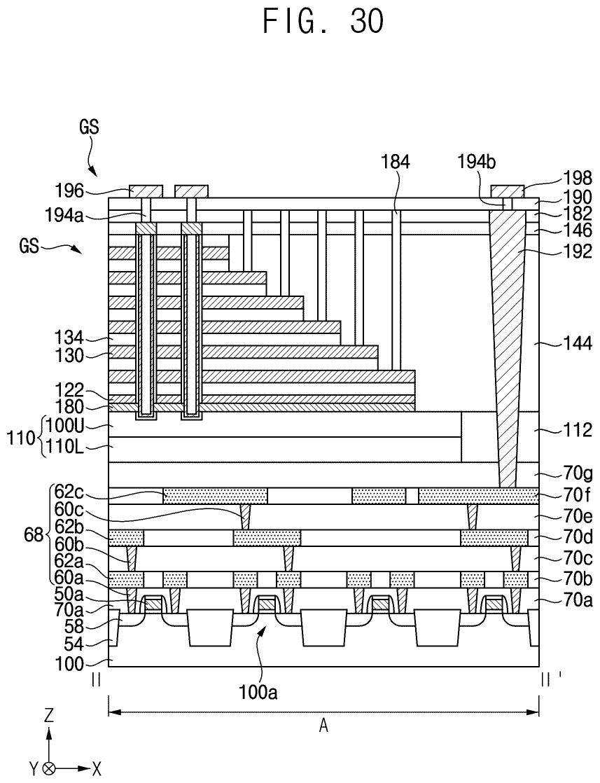

FIGS. 19 to 23, 28 and 29 are cross-sectional views taken along I-I′ and III-III′ lines of FIG. 4. FIGS. 24 to 26 are cross-sectional views taken along II-II′ and III-III′ lines of FIG. 4. FIG. 27 is a cross-sectional view taken along line I-I′ of FIG. 4, and FIG. 30 is a cross-sectional view taken along line II-II′.

Referring to FIG. 19, a shallow trench isolation process such as but not limited to a high-density plasma (HDP) operation may be performed on a lower substrate 100 to form an isolation pattern 54. A region where the isolation pattern 54 is not formed may serve as an active region. A first active region 100a may be formed in a first region A of the lower substrate 100, and a second active region 100b may be formed in a second region B of the lower substrate 100. The lower substrate 100 may have a bulk region doped with P-type impurities having low concentration. A first impurity region 56 may be formed by doping (e.g., implanting and/or implanting and annealing) the second active region 100b with N-type impurities.

A plurality of transistors constituting a peripheral circuit may be formed on the first region A of the lower substrate 100. Each of the plurality of transistors may include a lower gate 50a and second impurity regions 58 at the first active region 100a adjacent to both sides of the lower gate 50a.

A first lower insulating interlayer 70a may be formed to cover the lower substrate 100 and the plurality of transistors on the first and second regions A and B.

The first lower insulating interlayer 70a on the first and second regions A and B may be etched to form a first lower contact hole passing through the first lower insulating interlayer 70a on the first region A and a first discharge contact hole passing through the first lower insulating interlayer 70a on the second region B. In a plan view, the first lower contact hole may have a circular or elliptical shape, and the first discharge contact hole may have a line shape extending in the second direction Y. The second active region 100b may be exposed by a bottom of the first discharge contact hole.

A first conductive layer may be formed on the first lower insulating interlayer 70a to fill the first lower contact hole and the first discharge contact hole. The first conductive layer may include a metal material, e.g., tungsten. In some example embodiments, the first conductive layer may include polysilicon.

The first conductive layer may be planarized until an upper surface of the first lower insulating interlayer 70a may be exposed to form a first lower contact plug 60a on the first region A and a first discharge contact plug 64a on the second region B. The first discharge contact plug 64a may extend in the second direction Y. That is, the second direction Y may be a long axis direction of the first discharge contact plug 64a.

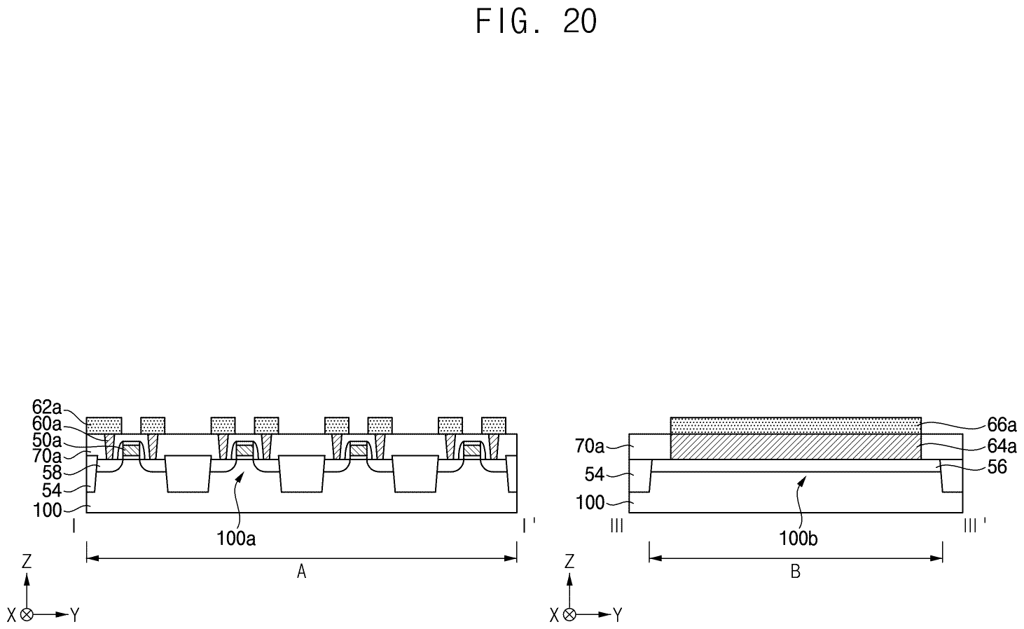

Referring to FIG. 20, a second conductive layer may be formed on the first lower insulating interlayer 70a, the first lower contact plug 60a and the first discharge contact plug 64a. The second conductive layer may be patterned to form a first lower conductive pattern 62a covering the first lower contact plug 60a on the first region A and a first discharge conductive pattern 66a covering the first discharge contact 64a on the second region B.

In some example embodiments, the first lower conductive pattern 62a may have a line shape extending in the first direction X or the second direction Y.

The first discharge conductive pattern 66a may extend in the second direction Y to completely cover the first discharge contact plug 64a. In some example embodiments, a width of the first discharge conductive pattern 66a in the first direction X may be substantially the same as a width of the first discharge contact plug 64a in the first direction X. In some exemplary embodiments, a width of the first discharge conductive pattern 66a in the first direction X may be greater than a width of the first discharge contact plug 64a in the first direction X.

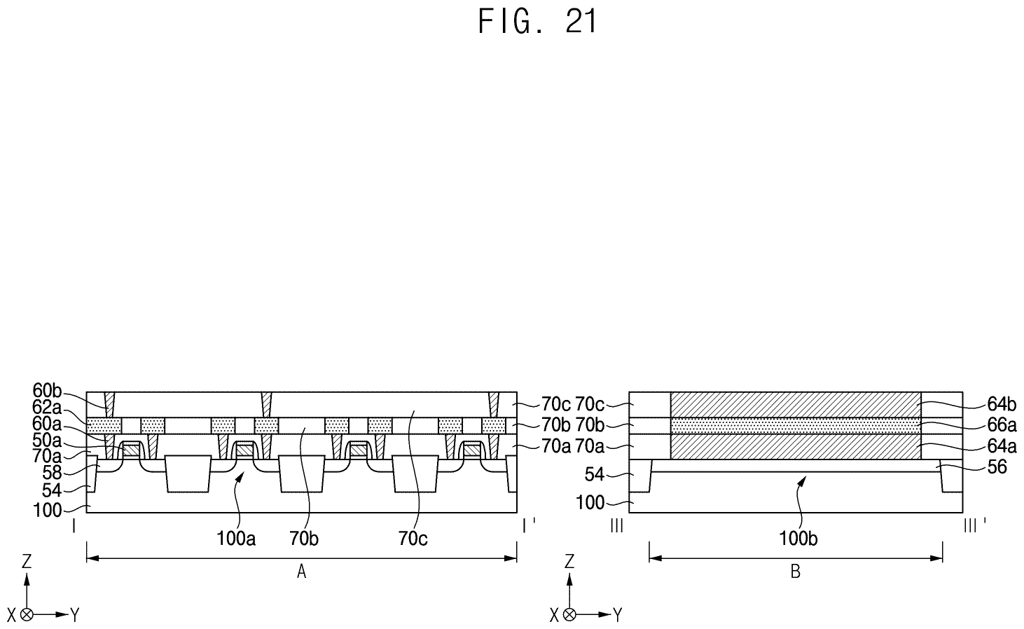

Referring to FIG. 21, a second lower insulating interlayer 70b may be formed on the first lower insulating interlayer 70a to cover the first discharge conductive pattern 66a and the first lower conductive pattern 62a. An upper surface of the second lower insulating interlayer 70b may be planarized.

A third lower insulating interlayer 70c may be formed on the first lower conductive pattern 62a, the first discharge conductive pattern 66a, and the second lower insulating interlayer 70b.

The third lower insulating interlayer 70c may be etched to form a second lower contact hole passing through the third lower insulating interlayer 70c on the first region A and a second discharge contact hole passing through the third lower insulating interlayer 70c on the second region B.

In a plan view, the second lower contact hole may have a circular or elliptical shape, and the second discharge contact hole may have a line shape extending in the second direction Y. The first discharge conductive pattern 66a may be exposed by a bottom of the second discharge contact hole. In some example embodiments, the second discharge contact hole may be disposed to overlap the first discharge contact hole. The first lower conductive pattern 62a may be exposed by a bottom of the second lower contact hole.

A third conductive layer may be formed on the third lower insulating interlayer 70c to fill the second lower contact hole and the second discharge contact hole. An upper surface of the third conductive layer may be planarized until an upper surface of the third lower insulating interlayer 70c may be exposed to form a second lower contact plug 60b on the first region A and a second discharge contact plug 64b on the second region B.

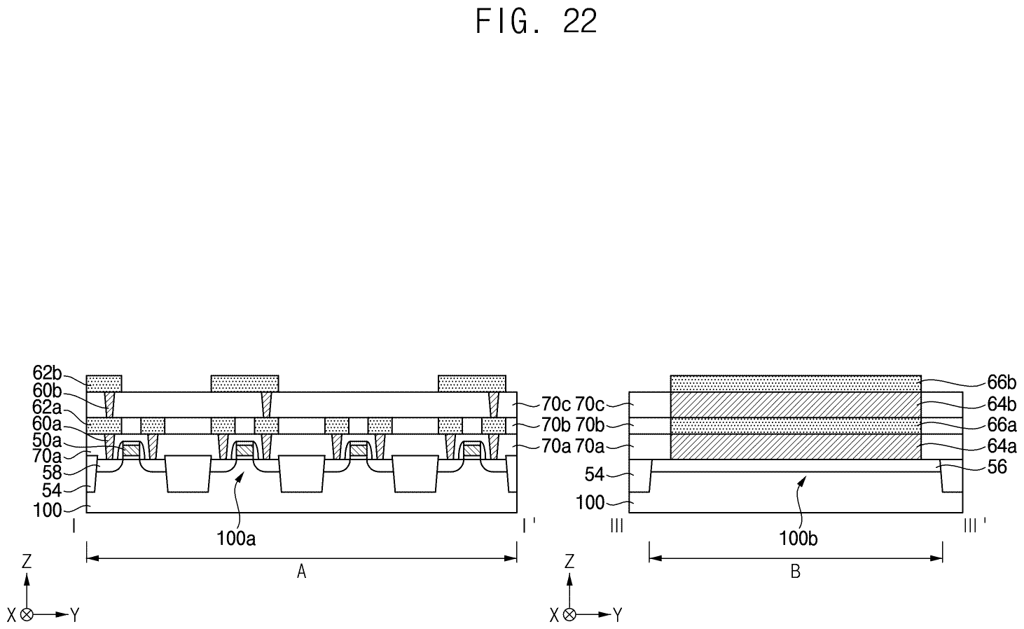

Referring to FIG. 22, a fourth conductive layer may be formed on the third lower insulating interlayer 70c, the second lower contact plug 60b and the second discharge contact plug 64b. The fourth conductive layer may be patterned to form a second lower conductive pattern 62b covering the second lower contact plug 60b in the first region A and a second discharge conductive pattern 66b covering the second discharge contact plug 64b on the second region B.

The second discharge conductive pattern 66b may extend in the second direction Y to completely cover the second discharge contact plug 64b. In some example embodiments, a width of the second discharge conductive pattern 66b in the first direction X may be the same as a width of the second discharge contact plug 64b in the first direction X. In some example embodiments, a width of the second discharge conductive pattern 66b in the first direction X may be greater than a width of the second discharge contact plug 64b in the first direction X.

In some example embodiments, the second discharge conductive pattern 66b may be disposed to overlap the first discharge conductive pattern 66a.

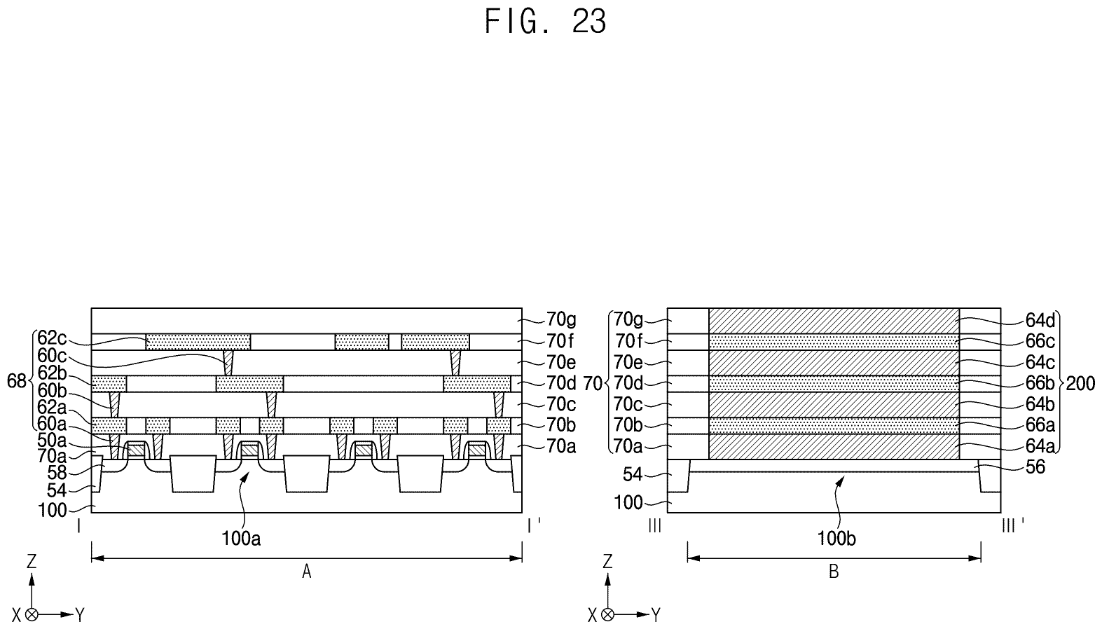

Referring to FIG. 23, a fourth lower insulating interlayer 70d may be formed on the third lower insulating interlayer 70c to cover the second discharge conductive pattern 66b and the second lower conductive pattern 62b. An upper surface of the fourth lower insulating interlayer 70d may be planarized.

Thereafter, the processes described with reference to FIGS. 19 and 20 may be repeatedly performed on the fourth lower insulating interlayer 70d, the second lower conductive pattern 62b, and the second discharge conductive pattern 66b. Accordingly, the multilayer wiring structure 68 may be formed on the first region A of the lower substrate 100 and the discharge conductive structure 200 may be formed on the second active region 100b of the lower substrate 100.

According to the above process, the multilayer wiring structure 68 in which a plurality of lower contact plugs 60a, 60b, and 60c and a plurality of lower conductive patterns 62a, 62b, and 62c are alternately stacked may be formed on the first region A of the lower substrate 100. Alternatively or additionally, the discharge structure 200 in which a plurality of discharge contact plugs 64a, 64b, 64c and 64d and a plurality of discharge conductive patterns 66a, 66b and 66c are alternately stacked may be formed on the second active region 100b of the lower substrate 100. The discharge structure 200 may include contact plugs one more than the contact plugs included in the multilayer wiring structure 68. A plurality of lower insulating interlayers 70a, 70b, 70c, 70d, 70e, 70f, and 70g may be formed to cover the multilayer wiring structure 68, and may fill spaces between the discharge structures 200. Hereinafter, the plurality of lower insulating interlayers 70a, 70b, 70c, 70d, 70e, 70f, and 70g may be collectively referred to as a lower insulating interlayer 70.

For example, as shown in FIG. 23, the multilayer wiring structure 68 may include the first lower contact plug 60a, the first lower conductive pattern 62a, the second lower contact plug 60b, the second lower conductive pattern 62b, a third lower contact plug 60c and a third lower conductive pattern 62c stacked. The discharge structure 200 may include the first discharge contact plug 64a, the first discharge conductive pattern 66a, the second discharge contact plug 64b, the second discharge conductive pattern 66b, a third discharge contact plug 64c, a third discharge conductive pattern 66c and a fourth discharge contact plug 64d stacked. An upper surface of the fourth discharge contact plug 64d disposed on an uppermost portion of the discharge structure 200 may be coplanar with an upper surface of an uppermost lower insulating interlayer (e.g., a seventh lower insulating interlayer 70g).

The discharge structure 200 may have a wall shape extending in the second direction Y.

Meanwhile, patterning processes for forming the discharge contact plugs 64a, 64b, 64c, 64d and the discharge conductive patterns 66a, 66b, 66c may be controlled, so that a shape of the discharge structure 200 may be changed.

In some example embodiments, a plurality of discharge structures 200 extending in the second direction Y and being spaced apart to each other in the first direction X may be formed on the second active region 100b.

In some example embodiments, as shown in FIGS. 12 and 13, the plurality of discharge structures 200a extending in the second direction Y and being spaced apart to each other in the first direction X and the second direction Y may be formed on the second active region 100b.

In some example embodiments, in patterning processes for forming the discharge contact plugs 64a, 64b, 64c and 64d and the discharge conductive patterns 66a, 66b and 66c may be formed the wire passage region 80 (refer to FIG. 14) together. Accordingly, the discharge structure 200b shown in FIG. 14 may be formed.

In some example embodiments, the discharge contact plugs 64a, 64b, 64c and 64d and the discharge conductive patterns 66a, 66b and 66c may be patterned to have a mesh shape. In this case, the discharge structure 200c shown in FIGS. 15 and 16 may be formed.

In some example embodiments, the discharge contact plugs 64a, 64b, 64c and 64d and the discharge conductive patterns 66a, 66b and 66c may be patterned so that an extension direction (e.g., the long axis direction) of the discharge contact plugs 64a, 64b, 64c and 64d and an extension direction of the discharge conductive patterns 66a, 66b and 66c may cross to each other. In this case, the discharge structure 200d shown in FIGS. 17 and 18 may be formed.

Referring to FIG. 24, a common source plate 110 may be formed on the multilayer wiring structure 68, the discharge structure 200 and the seventh lower insulating interlayer 70g. A portion of the common source plate 110 may be etched to form an opening, and a lower filling insulation pattern 112 may be formed to fill the opening.

The common source plate 110 may be disposed to overlap the lower substrate 100. In some example embodiments, a horizontal area of the common source plate 110 may be less than a horizontal area of the lower substrate 100. In some example embodiments, a metal plate 110L and a semiconductor plate 110U may be sequentially stacked on the lower substrate 100 to form the common source plate 110. In some example embodiments, the common source plate 110 may include only the semiconductor plate 110U without the metal plate 110L. The semiconductor plate 110U may include polysilicon.

A lower portion of the common source plate 110 may directly contact the discharge structure 200. For example, a lower surface of the common source plate 110 may directly contact the fourth discharge contact plug 64d disposed at the uppermost portion of the discharge structure 200.

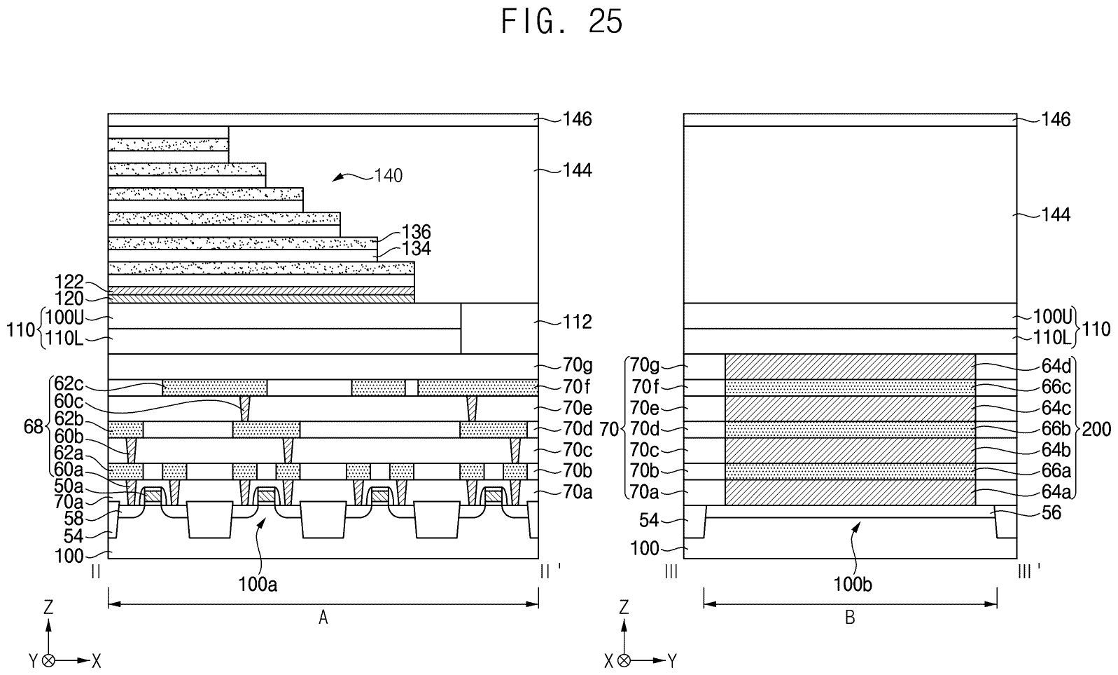

Referring to FIG. 25, a sacrificial layer structure 120 and a support layer 122 may be formed on the common source plate 110 and the lower filling insulation pattern 112. Insulation layers 134 and the sacrificial layers 136 may be alternately and repeatedly stacked on the support layer 122. The insulation layers 134 may include silicon oxide. The sacrificial layers 136 may include silicon nitride or silicon carbide. The sacrificial layers 136 may serve as a space for forming a plurality of gate patterns 130 by subsequent processes.

Portions of the insulation layers 134 and the sacrificial layers 136A may be repeatedly etched to form a mold structure 140. An edge of the mold structure 140 in the first direction X may have a stepped shape.

A first insulating interlayer 144 may be formed to cover sidewalls of the mold structure 140. A second insulating interlayer 146 may be formed to cover the mold structure 140 and the first insulating interlayer 144.

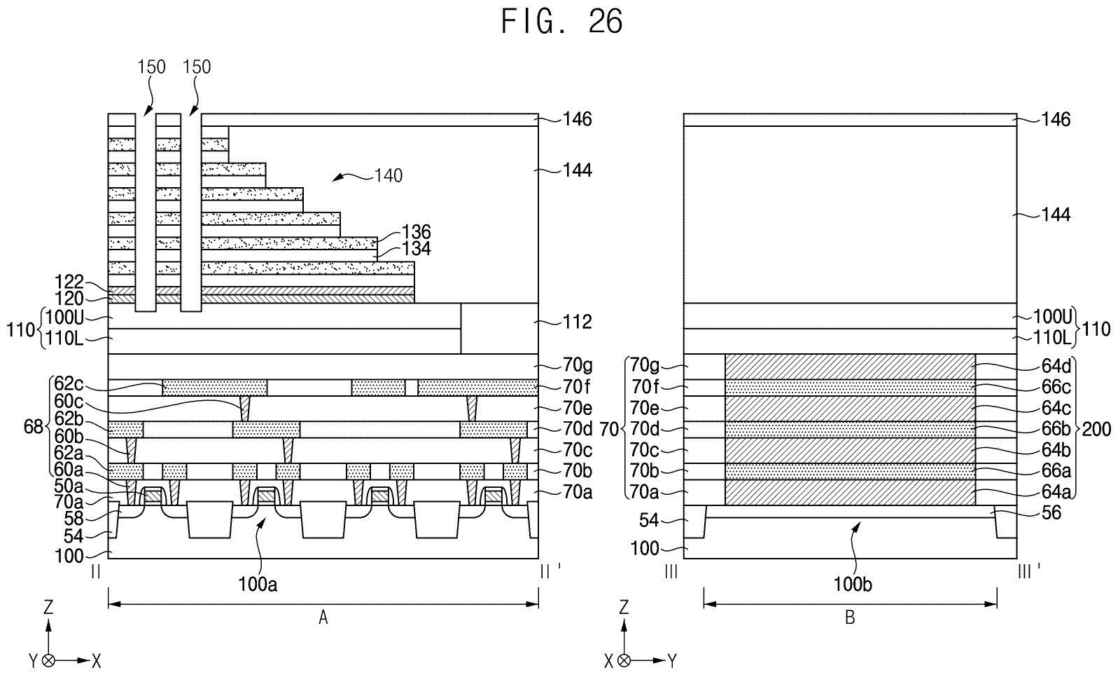

FIGS. 26 and 27, portions of the second insulating interlayer 146, the first insulating interlayer 144, the sacrificial layer structure 120, the support layer 122, and the mold structure 140 may be etched to form channel holes 150 exposing an upper portion of the common source plate 110.

An etching process for forming the channel holes 150 may include a plasma etching process. Due to high integration of the semiconductor device, the number of channel holes 150 formed by the plasma etching process may increase. Further, an etching depth for forming the channel holes 150 may increase. When the plasma etching process is performed, a high voltage may be required. Electrical charges may be accumulated in the common source plate 110, during the plasma etching process.

If there is no discharge path between the common source plate 110 and the lower substrate 100, an arcing occurs between the common source plate 110 and the lower substrate 100 due to the charges accumulated in the common source plate 110. An insulation breakdown in the peripheral circuit due to the arcing may occur, and a reliability of the semiconductor device may be decreased.

However, when the plasma etching process is performed, the charges may move through the discharge structure 200 disposed between the common source plate and the lower substrate 100, and the charges may be discharged to the lower substrate 100 through a zener diode of the second active region 100b. Accordingly, the insulation breakdown due to the arcing may be prevented or reduced in likelihood of and/or in impact from occurring.

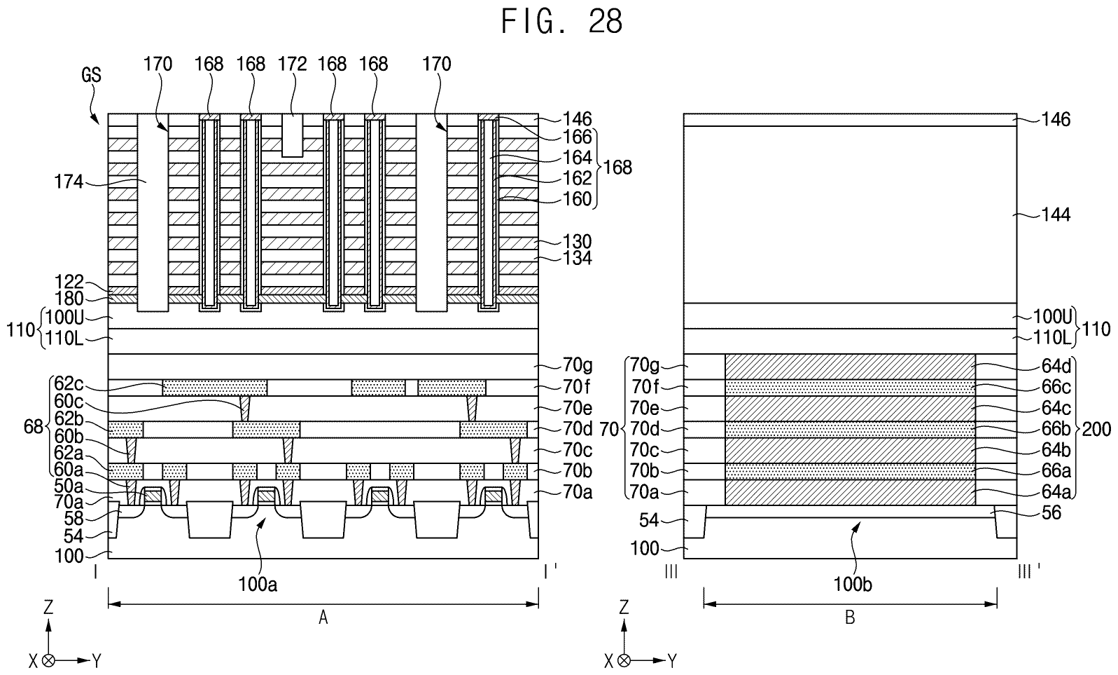

Referring to FIG. 28, a preliminary channel structure may be formed in the channel hole 150. The preliminary channel structure may include a preliminary gate dielectric layer, a channel pattern 162, a filling insulation pattern 164 and a capping pattern 166.

An upper portion of the mold structure 140 may be etched to form a string selection line cut region, and then an upper insulation pattern 172 may be formed to fill the string selection line cut region.

The second insulating interlayer 146, the first insulating interlayer 144, and the mold structure 140 may be etched to form a plurality of word line cut regions 170. Each of the word line cut regions 170 may pass through the second insulating interlayer 146, the first insulating interlayer 144 and the mold structure 140. An upper portion of the common source plate 110 may be exposed by bottoms of the word line cut regions 170.

The sacrificial layer structure 120 may be removed using etchant supplying through the word line cut regions 170 to form a first gap. The preliminary gate dielectric layer exposed by the first gap may be etched to form a gate dielectric layer 160. Accordingly, the gate dielectric layer 160 may be divided into an upper gate dielectric layer and a lower gate dielectric layer. A channel structure 168 including a gate dielectric layer 160, the channel pattern 162, the filling insulation pattern 164 and the capping pattern 166 may be formed in the channel hole 150.

A conductive material may fill the first gap to form a channel connection pattern 180. The channel connection pattern 180 may include, e.g., polysilicon. The channel connection pattern 180 may connect channel patterns 162 in adjacent channel structures 168 to each other, and channel connection pattern 180 the may connect the channel patterns 162 and the common source plate 110 to each other.

Thereafter, the sacrificial layers in the mold structure 140 may be removed to form second gaps. Gate patterns 130 may be formed in the second gaps, respectively.

Accordingly, a gate stack GS in which the insulation layers 134 and the gate patterns 130 are alternately and repeatedly stacked may be formed on the common source plate 110.

Thereafter, a second filling insulation pattern 174 may be formed to fill the word line cut region 170.

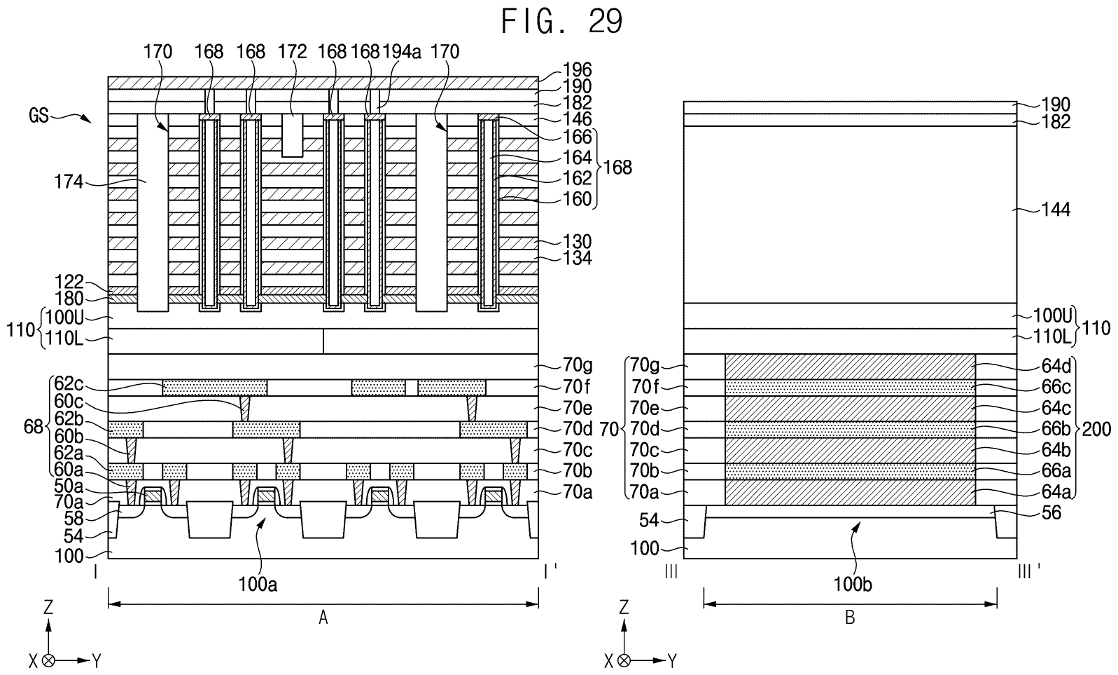

Referring to FIGS. 29 and 30, a third insulating interlayer 182 may be formed on the second insulating interlayer 146. Cell contact plugs 184 may be formed through the third insulating interlayer 182, the second insulating interlayer 146, and the first insulating interlayer 144. The cell contact plugs 184 may contact step portions of gate patterns 130, respectively.

Portions of the third insulating interlayer 182, the second insulating interlayer 146, the first insulating interlayer 144, the lower filling insulation pattern 112 and the lower insulating interlayer 70 may be etched to form a through via hole exposing an upper surface of the multilayer wiring structure 68. In some example embodiments, an upper surface of an uppermost lower conductive pattern may be exposed by a lower surface of the through via hole.

In some example embodiments, the through via hole may be formed to be spaced apart from the gate stack GS in a horizontal direction. In some example embodiments, some through via holes may be formed to pass through the gate stack GS without contacting the gate patterns 130.

Then, a conductive material may fill the through via hole to form a through via 192.

A fourth insulating interlayer 190 may be formed on the third insulating interlayer 182, the cell contact plugs 184 and the through vias 192.

A first contact 194a contacting the capping pattern 166 in the channel structure 168 and a second contact 194b contacting the through via 192 may be formed through the fourth insulating interlayer 190 and the third insulating interlayer 182. In addition, a bit line 196 may be formed on the first contact 194a. A wiring line 198 may be formed on the second contact 194b.

By performing the above processes, a vertical memory device may be manufactured.

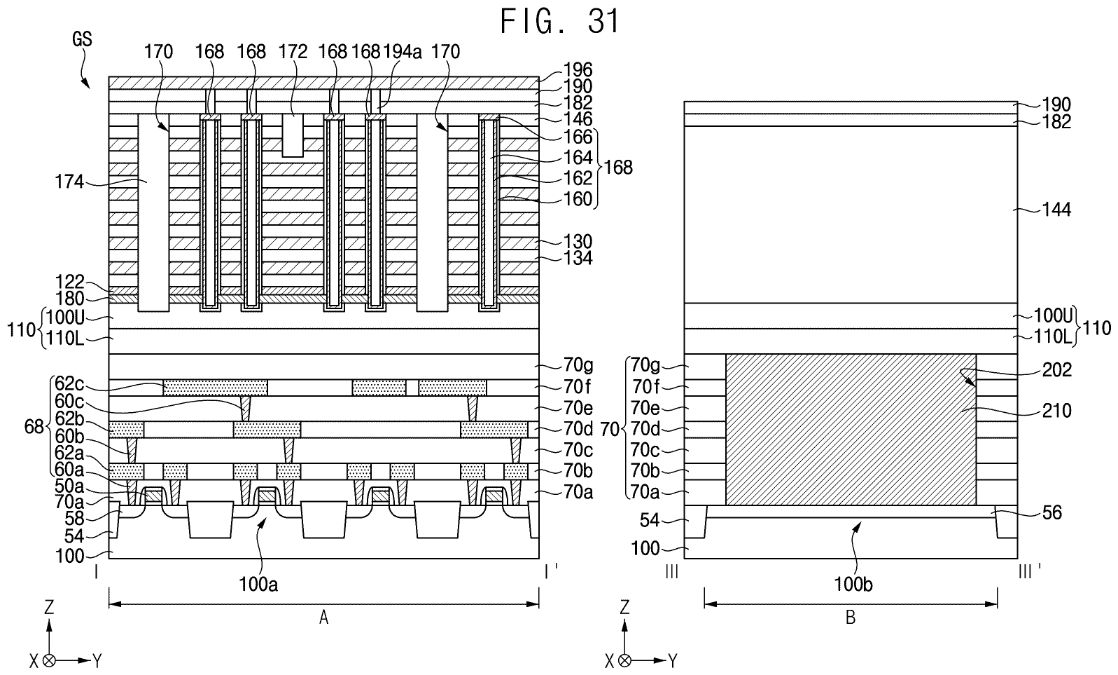

FIG. 31 is a cross-sectional view of a vertical memory device according to various example embodiments.

FIG. 31 is a cross-sectional view taken along the line I-I′ and the line III-III′ of FIG. 4.

The semiconductor device may be substantially the same as the semiconductor device described with reference to FIG. 6, except for a discharge structure. Therefore, only the discharge structure may be described.

The discharge structure 210 may include one conductive material extending in the second direction Y. That is, the discharge structure 210 may have a structure in which a conductive material is filled in a trench 202 extending in the second direction Y. The discharge structure 210 may be formed by separate processes, after forming the multilayer wiring structure 68.

In some example embodiments, as an arrangement similar to that of FIG. 9, a plurality of discharge structures 210 extending in the second direction Y and being spaced apart in the first direction X may be formed on the second active region 100b. In some example embodiments, as an arrangement similar to that of FIG. 12, a plurality of discharge structures 210 extending in the second direction may be spaced apart from each other in each of first and second directions X and Y on the second active region 100b.

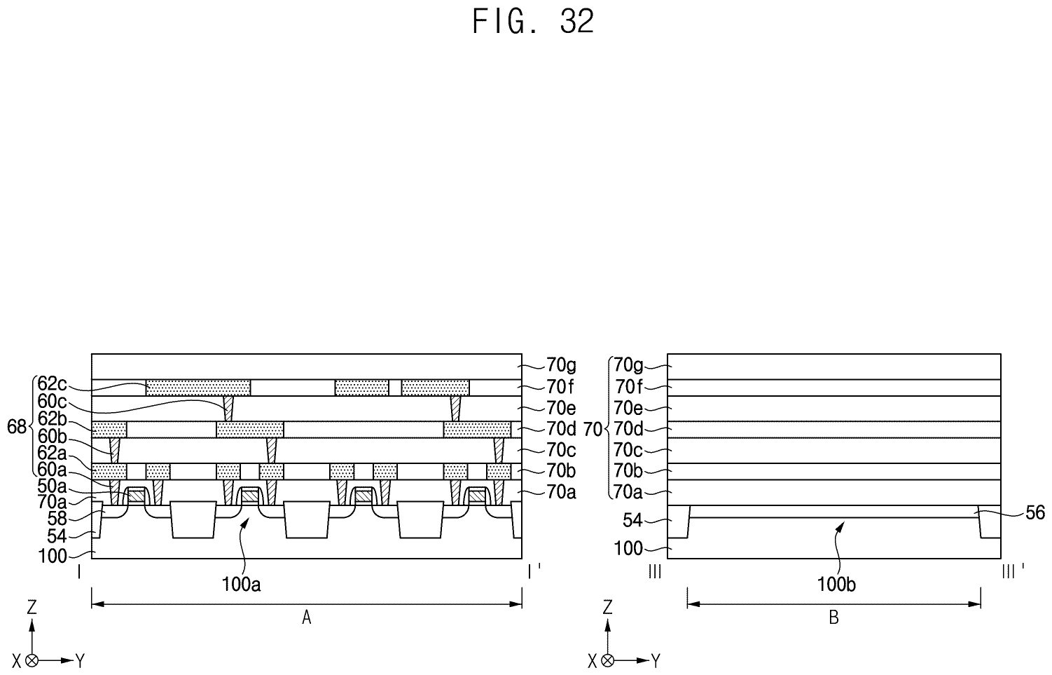

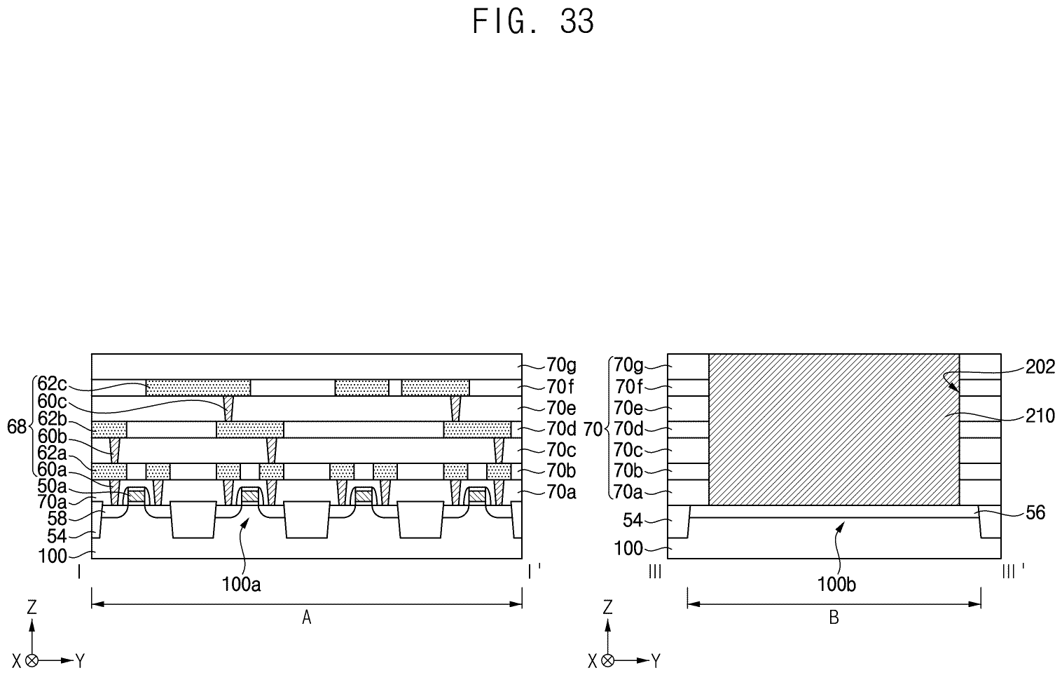

FIGS. 32 and 33 are cross-sectional views illustrating a method of manufacturing a vertical memory device according to various example embodiments.

FIGS. 32 and 33 are cross-sectional views taken along I-I′ and III-III′ lines of FIG. 4.

Referring to FIG. 32, a first active region 100a may be formed on the first region A of the lower substrate 100, and a second active region 100b may be formed on the second region B of the lower substrate 100.

A plurality of transistors constituting a peripheral circuit may be formed on the first region A of the lower substrate 100.

A multilayer wiring structure 68 may be formed on the first region A of the lower substrate 100. In addition, lower insulating interlayers 70 may be formed to cover the multilayer wiring structure 68.

When the multilayer wiring structure 68 is formed on the first region A of the lower substrate 100, the discharge structure may not be formed on the second region B of the lower substrate 100. For example, the lower insulating interlayers 70 may cover the second region B of the lower substrate 100.

For example, the multilayer wiring structure 68 in which a plurality of lower contact plugs 60a, 60b, and 60c and a plurality of lower conductive patterns 62a, 62b, and 62c are alternately stacked on the first region A of the lower substrate 100. First to seventh lower insulating interlayers 70a, 70b, 70c, 70d, 70e, 70f, and 70g may be formed on the first region A of the lower substrate 100 to cover the multilayer wiring structure 68. The first to seventh lower insulating interlayers 70a, 70b, 70c, 70d, 70e, 70f, and 70g may be formed on the second active region 100b of the lower substrate 100.

Referring to FIG. 33, the first to seventh lower insulating interlayers 70a, 70b, 70c, 70d, 70e, 70f, and 70g on the second region B of the lower substrate 100 may be etched to form a trench 202 exposing the second active region 100b. The trench 202 may extend in the second direction Y. The trench 202 may define a region where a discharge structure is formed.

A conductive layer may be formed on the seventh lower insulating interlayer 70g to fill the trench 202. The conductive layer may be planarized until an upper surface of the seventh lower insulating interlayer 70g may be exposed to form the discharge structure 210 filling the trench 202.

Thereafter, the same processes as described with reference to FIGS. 24 to 30 may be performed to manufacture the vertical memory device shown in FIG. 31.

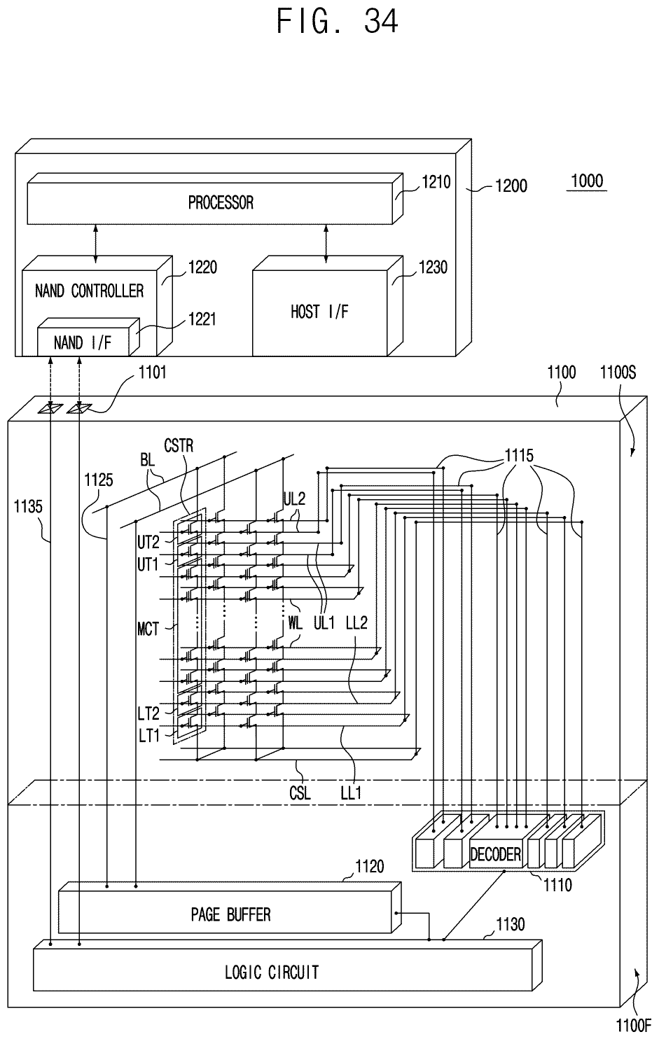

FIG. 34 is a diagram schematically illustrating an electronic system including a semiconductor device according to various example embodiments.

Referring to FIG. 34, an electronic system 1000 may include a semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device including one or a plurality of semiconductor devices 1100, a universal serial bus (USB), a computing system, a medical device, or a communication device.

The semiconductor device 1100 may be a nonvolatile memory device. As described above, the semiconductor device 1100 may be a vertical memory device including the discharge structure having the wall shape (refer to FIG. 5, 200). The semiconductor device 1100 may include a first structure 1100F and a second structure 1100S on the first structure 1100F. The first structure 1100F may be a peripheral circuit structure including a decoder circuit 1110, a page buffer 1120, and a logic circuit 1130. The discharge structure may be included in the peripheral circuit structure.

The second structure 1100S includes a bit line BL, a common source line CSL, word lines WL, first and second gate upper lines UL1 and UL2, and first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may be variously modified.

In some example embodiments, the upper transistors UT1 and UT2 may include string select transistors, and the lower transistors LT1 and LT2 may include ground select transistors. The lower gate patterns LL1 and LL2 may be gate electrodes of the lower transistors LT1 and LT2, respectively. The word lines WL may be gate electrodes of the memory cell transistors MCT, and the upper gate patterns UL1 and UL2 may be gate electrodes of the upper transistors UT1 and UT2, respectively.

In some example embodiments, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT1 may performs an erase operation of data stored in the memory cell transistors MCT using a gate induce drain leakage (GIDL) phenomenon.

The common source line CSL, the first and second lower gate patterns LL1 and LL2, the word lines WL, and the first and second upper gate patterns UL1 and UL2 may be electrically connected to the decoder circuit through the first connection wirings 1115 extending from the first structure 1100F to the second structure 1100S. The bit lines BL may be electrically connected to the page buffer 1120 through second connection wirings 1125 extending from the first structure 1100F to the second structure 1100S.

In the first structure 1100F, the decoder circuit 1110 and the page buffer 1120 may control at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pad 1101 may be electrically connected to the logic circuit 1130 through an input/output connection wire 1135 extending from the first structure 1100F to the second structure 1100S.

The controller 1200 may include a processor 1210, a NAND controller 1220, and a host interface 1230. In some example embodiments, the electronic system 1000 may include a plurality of semiconductor devices 1100. In this case, the controller 1200 may control the plurality of semiconductor devices 1000.

The processor 1210 may control overall operations of the electronic system 1000 including the controller 1200. The processor 1210 may operate according to predetermined firmware and may access the semiconductor device 1100 by controlling the NAND controller 1220. The NAND controller 1220 may include a NAND interface 1221 that processes communication with the semiconductor device 1100. A control command for controlling the semiconductor device 1100, write data in the memory cell transistors MCT of the semiconductor device 1100, and read data from the memory cell transistors MCT of the semiconductor device 1100 may be transmitted by the NAND interface 1221.

A host interface 1230 may provide a communication function between the electronic system 1000 and an external host. When the control command is received from an external host through the host interface 1230, the processor 1210 may control the semiconductor device 1100 in response to the control command.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While inventive concepts have been shown and described with reference to various example embodiments thereof, it will be understood by those of ordinary skill in the art that various changes in form and details may be made thereto without departing from the spirit and scope of inventive concepts as set forth by the following claims. Furthermore example embodiments are not necessarily mutually exclusive with one another. For example, some example embodiments may include one or more features described with reference to one or more figures, and may also include one or more other features described with reference to one or more other figures.

What is claimed is:

1. A semiconductor device, comprising:
a lower substrate;
an active region on the lower substrate;
a common source plate spaced apart from an upper surface of the lower substrate in a vertical direction, and the common source plate at least partly overlapping the upper surface of the lower substrate;
a discharge structure directly connecting the common source plate and the active region in the vertical direction, the discharge structure having a structure in which a plurality of discharge contact plugs and a plurality of discharge conductive patterns are alternately stacked; and
a cell array structure on the common source plate, wherein
the discharge contact plugs extend parallel to the upper surface of the lower substrate, and
the conductive patterns extend parallel to the upper surface of the lower substrate.

2. The semiconductor device of claim 1, wherein the lower substrate includes P-type impurities, and the active region is includes N-type impurities, such that the lower substrate and the active region correspond to a Zener diode.

3. The semiconductor device of claim 1, wherein the discharge contact plugs and the discharge conductive patterns independently include at least one of a metal or polysilicon.

4. The semiconductor device of claim 1, wherein
the discharge contact plugs and the conductive patterns extend in the same direction, and
each of the discharge conductive patterns covers an upper surface of a discharge contact plug thereunder.

5. The semiconductor device of claim 4, wherein a length of each of the discharge contact plugs extending direction is greater than a width of each of the discharge conductive patterns contacting the discharge contact plugs.

6. The semiconductor device of claim 1, wherein
the discharge contact plugs and the conductive patterns extend in the same direction,
at least one of the discharge conductive patterns and the discharge contact plugs contacting the discharge conductive patterns include a cut portion, and
the discharge structure includes a wire passage region corresponding to the cut portion.

7. The semiconductor device of claim 6, further comprising:
a wiring passing through the wire passage region, wherein
the wiring is electrically insulated from the discharge structure.

8. The semiconductor device of claim 1, wherein
the discharge contact plugs and the conductive patterns extend in directions perpendicular to each other, and
the discharge contact plugs and the discharge conductive patterns cross each other.

9. The semiconductor device of claim 1, wherein
the discharge structure includes a plurality of discharge structures, and
the plurality of discharge structures are disposed to be spaced apart from each other.

10. The semiconductor device of claim 1, wherein the cell array structure includes:
a gate stack on the common source plate, the gate stack including a plurality of gate patterns spaced apart from each other in the vertical direction and an insulation layer interposed between the gate patterns; and
a plurality of channel structures passing through the gate stack in the vertical direction, and the plurality of channel structures contacting an upper portion of the common source plate.

11. The semiconductor device of claim 1, further comprising:
a peripheral circuit on the lower substrate,
wherein the peripheral circuit is spaced apart from the discharge structure, and includes a peripheral circuit pattern and a multilayer wiring structure.

12. The semiconductor device of claim 11, wherein
the multilayer wiring structure has a structure in which a plurality of lower contact plugs and a plurality of lower conductive patterns are alternately stacked,
each of the lower contact plugs and each of the discharge contact plug positioned at a first same level, and
each of the lower conductive patterns and each of the discharge conductive patterns positioned at a second same level.

13. A semiconductor device, comprising:
a lower substrate;
an active region on the lower substrate;
a common source plate spaced apart from an upper surface of the lower substrate in a vertical direction, the common source plate at least partly overlapping the upper surface of the lower substrate;
a discharge structure directly connecting the common source plate and the active region in the vertical direction, the discharge structure having a wall shape extending in a first direction parallel to the upper surface of the lower substrate; and
a cell array structure on the common source plate, wherein
a length of the discharge structure in the first direction is greater than a width of the discharge structure in a second direction parallel to the upper surface of the lower substrate and perpendicular to the first direction.

14. The semiconductor device of claim 13, wherein the discharge structure has a structure in which a plurality of discharge contact plugs and a plurality of discharge conductive patterns are alternately stacked.

15. The semiconductor device of claim 14, wherein a long axis direction of the discharge contact plugs and a long axis direction of the discharge conductive patterns are in the first direction.

16. The semiconductor device of claim 14, wherein the discharge structure includes a wire passage region passing through the discharge structure in the second direction.

17. The semiconductor device of claim 16, further comprising:
a wiring passing through the wire passage region,
wherein the wiring is electrically insulated from the discharge structure.

18. A semiconductor device, comprising:
a lower substrate;
a peripheral circuit including a peripheral circuit pattern and a multilayer wiring structure on the lower substrate;
an active region on the lower substrate, the active region including N-type impurities;
a common source plate spaced apart from an upper surface of the lower substrate in a vertical direction, the common source plate at least partly overlapping the upper surface of the lower substrate;
a discharge structure directly connecting the common source plate and the active region in the vertical direction, the discharge structure including a plurality of discharge contact plugs and a plurality of discharge conductive patterns alternately stacked;
a gate stack on the common source plate, the gate stack including a plurality of gate patterns spaced apart from each other in the vertical direction and an insulation layer interposed between the gate patterns; and
a channel structure passing through the gate stack in the vertical direction, the channel structure contacting an upper portion of the common source plate, wherein
the discharge conductive patterns and the discharge contact plugs extend in a first direction parallel to the upper surface of the lower substrate such that the first direction is a long axis direction of each of discharge conductive patterns and the discharge contact plugs, and
a length of each of the discharge contact plugs in the first direction is greater than a width of each of the discharge conductive patterns contacting each discharge contact plugs.

19. The semiconductor device of claim 18, wherein the discharge structure has a wall shape extending in the first direction.

20. The semiconductor device of claim 18, wherein the multilayer wiring structure has a structure in which a plurality of lower contact plugs and a plurality of lower conductive patterns are alternately stacked.
